(19) United States
(12) Patent Application Publication
(10) Pub. No.: US 2024/0347554 A1
(43) Pub. Date: Oct. 17, 2024

(54) IMAGING ELEMENT AND IMAGING DEVICE

(71) Applicant: SONY SEMICONDUCTOR SOLUTIONS CORPORATION, KANAGAWA (JP)

(72) Inventors: KAZUNORI KURISHIMA, KANAGAWA (JP); MASAKAZU MUROYAMA, KANAGAWA (JP)

(21) Appl. No.: 18/685,326

(22) PCT Filed: Mar. 17, 2022
(86) PCT No.: PCT/JP2022/012402

§ 371 Date: Feb. 21, 2024

(30) Foreign Application Priority Data
Sep. 10, 2021 (JP) 2021-147548

(51) Int. Cl. H01L 27/146; H10K 39/32

(52) U.S. Cl. CPC H01L 27/14601; H10K 39/32

(57) ABSTRACT

An imaging element according to an embodiment of the present disclosure includes: a first electrode and a second electrode that are disposed in parallel; a third electrode that is disposed to be opposed to the first electrode and the second electrode; a photoelectric conversion layer that is provided between the first electrode and second electrode, and the third electrode, and includes an organic material; and a semiconductor layer including a first layer and a second layer that are stacked in order from side of the first electrode and the second electrode between the first electrode and second electrode, and the photoelectric conversion layer. The first layer includes a first oxide material having a carrier concentration of 1E19 cm⁻³ or more and 1E21 cm⁻³ or less and bond dissociation energy of 3.58 eV or more and 5.50 eV or less, and the second layer includes the first oxide material and a second oxide material having a band gap of 4.5 eV or more and bond dissociation energy of 4.0 eV or more and 8.8 eV or less.

### TECHNICAL FIELD

The present disclosure relates to an imaging element in which, for example, an organic material is used and an imaging device including the imaging element.

### BACKGROUND ART

For example, PTL 1 discloses an imaging element including an accumulation electrode, a second insulating layer, a semiconductor layer, a collection electrode, a photoelectric conversion layer, and an upper electrode, and the semiconductor layer is formed using, for example, IGZO. For example, PTL2 discloses an imaging element including a semiconductor layer having a stacked structure. The semiconductor layer in PTL 2 is formed using indium composite oxide, and a lower layer has a higher indium composition than an upper layer. For example, PTL 3 discloses an imaging element including a semiconductor layer having a stacked structure, as with PTL 2. The semiconductor layer in PTL 3 is formed using IGZO, and is configured to cause an upper layer to have a higher band gap than a lower layer.

### CITATION LIST

### Patent Literature

PTL 1: Japanese Unexamined Patent Application Publication No. 2016-63165

PTL 2: International Publication No. WO2019/035252

PTL 3: Japanese Unexamined Patent Application Publication No. 2012-164978

### SUMMARY OF THE INVENTION

Incidentally, an imaging element is desired to have improved transfer characteristics and improved afterimage characteristics.

It is desirable to provide an imaging element and an imaging device each of which makes it possible to improve transfer characteristics and afterimage characteristics.

An imaging element according to an embodiment of the present disclosure includes: a first electrode and a second electrode that are disposed in parallel; a third electrode that is disposed to be opposed to the first electrode and the second electrode; a photoelectric conversion layer that is provided between the first electrode and second electrode, and the third electrode, and includes an organic material; and a semiconductor layer including a first layer and a second layer that are stacked in order from side of the first electrode and the second electrode between the first electrode and second electrode, and the photoelectric conversion layer. The first layer includes a first oxide material having a carrier concentration of 1E19 cm⁻³ or more and 1E21 cm⁻³ or less and bond dissociation energy of 3.58 eV or more and 5.50 eV or less, and the second layer includes the first oxide material and a second oxide material having a band gap of 4.5 eV or more and bond dissociation energy of 4.0 eV or more and 8.8 eV or less.

An imaging device according to an embodiment of the present disclosure includes one or a plurality of imaging elements according to the embodiment of the present disclosure described above for each of a plurality of pixels.

In the imaging element according to the embodiment of the present disclosure and the imaging device according to the embodiment of the present disclosure, the semiconductor layer is provided between the first electrode and the second electrode that are disposed in parallel, and the photoelectric conversion layer. The semiconductor layer includes the first layer and the second layer that are stacked in this order from side of the first electrode and the second electrode. The first layer is formed using the first oxide material having a carrier concentration of 1E19 cm⁻³ or more and 1E21 cm⁻³ or less and bond dissociation energy of 3.58 eV or more and 5.50 eV or less. In a first imaging element, the second layer is formed using the first oxide material and a second oxide material having a band gap of 4.5 eV or more and bond dissociation energy of 4.0 eV or more and 8.8 eV or less. This reduces electric charges generated in the photoelectric conversion layer to stagnate at an interface between the photoelectric conversion layer and the semiconductor layer, and causes electric charges to move well in the semiconductor layer.

### BRIEF DESCRIPTION OF DRAWINGS

FIG. 1 is a schematic cross-sectional view of an example of a configuration of an imaging element according to an embodiment of the present disclosure.

FIG. 2 is a schematic plan view of an example of a pixel configuration of an imaging device including the imaging element illustrated in FIG. 1.

FIG. 3 is a schematic cross-sectional view of an example of a configuration of a photoelectric converter illustrated in FIG. 1.

FIG. 4 is an equivalent circuit diagram of the imaging element illustrated in FIG. 1.

FIG. 5 is a schematic view of disposition of a lower electrode and a transistor included in a controller in the imaging element illustrated in FIG. 1.

FIG. 6 is a cross-sectional view for describing a method of manufacturing the imaging element illustrated in FIG. 1.

FIG. 7 is a cross-sectional view of a process subsequent to FIG. 6.

FIG. 8 is a cross-sectional view of a process subsequent to FIG. 7.

FIG. 9 is a cross-sectional view of a process subsequent to FIG. 8.

FIG. 10 is a cross-sectional view of a process subsequent to FIG. 9.

FIG. 11 is a cross-sectional view of a process subsequent to FIG. 10.

FIG. 12 is a timing chart illustrating an operation example of the imaging element illustrated in FIG. 1.

FIG. 13 is a diagram describing an elemental composition in a second layer of a semiconductor layer illustrated in FIG. 1.

FIG. 14 is a schematic cross-sectional view of a configuration of a photoelectric converter according to a modification example 1 of the present disclosure.

FIG. 15 is a schematic cross-sectional view of an example of a configuration of a photoelectric converter according to a modification example 2 of the present disclosure.

FIG. 16 is a schematic cross-sectional view of an example of a configuration of an imaging element according to a modification example 3 of the present disclosure.

FIG. 17A is a schematic cross-sectional view of an example of a configuration of an imaging element according to a modification example 4 of the present disclosure.

FIG. 17B is a schematic plan view of the imaging element illustrated in FIG. 17A.

FIG. 18A is a schematic cross-sectional view of an example of a configuration of an imaging element according to a modification example 5 of the present disclosure.

FIG. 18B is a schematic plan view of the imaging element illustrated in FIG. 18A.

FIG. 19 is a block diagram illustrating an entire configuration of an imaging device including the imaging element illustrated in FIG. 1 or the like.

FIG. 20 is a block diagram illustrating an example of a configuration of an electronic apparatus including the imaging device illustrated in FIG. 19.

FIG. 21A is a schematic view of an example of an entire configuration of a photodetection system using the imaging device illustrated in FIG. 19.

FIG. 21B is a diagram illustrating an example of a circuit configuration of the photodetection system illustrated in FIG. 21A.

FIG. 22 is a view depicting an example of a schematic configuration of an endoscopic surgery system.

FIG. 23 is a block diagram depicting an example of a functional configuration of a camera head and a camera control unit (CCU).

FIG. 24 is a block diagram depicting an example of schematic configuration of a vehicle control system.

FIG. 25 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. The following description is a specific example of the present disclosure, and the present disclosure is not limited to the following embodiments. In addition, the present disclosure is not limited to arrangements, dimensions, dimension ratios, etc. of respective components illustrated in each drawing. It is to be noted that description is given in the following order.
1. Embodiment (An example of an imaging element in which a semiconductor layer having a predetermined carrier concentration, predetermined bond dissociation energy, and a predetermined band gap is stacked between a lower electrode and a photoelectric conversion layer)
1-1. Configuration of Imaging Element
1-2. Method of Manufacturing Imaging Element
1-3. Signal Acquisition Operation of Imaging Element
1-4. Workings and Effects
2. Modification Examples
2-1. Modification Example 1 (An example in which a transfer electrode is further provided as a lower electrode)
2-2. Modification Example 2 (An example in which a protective layer is further provided between the semiconductor layer and the photoelectric conversion layer)
2-3. Modification Example 3 (Another example of the configuration of the imaging element)
2-4. Modification Example 4 (Another example of the configuration of the imaging element)
2-5. Modification Example 5 (Another example of the configuration of the imaging element)
3. Application Examples
4. Practical Application Examples
5. Examples

### 1. Embodiment

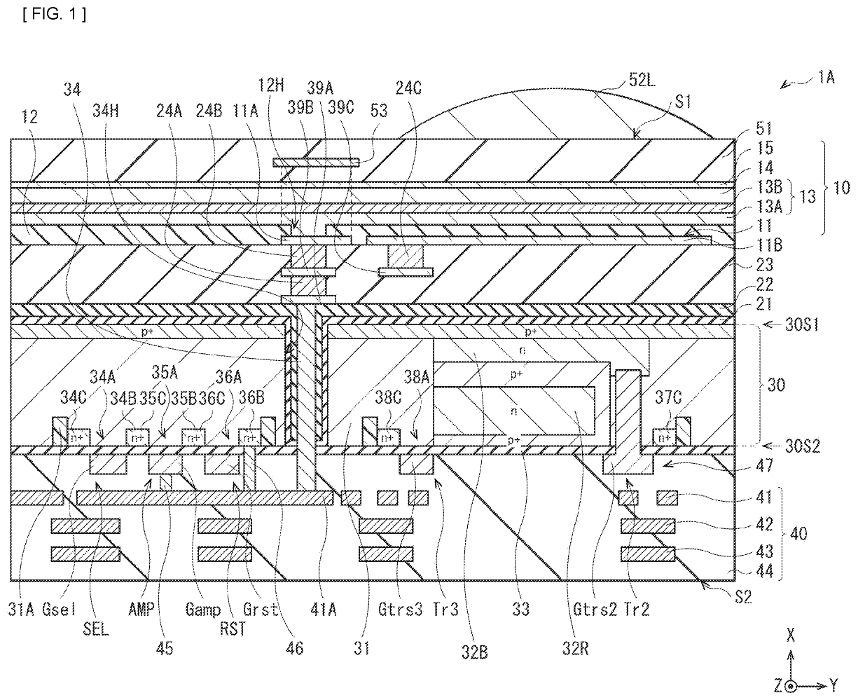

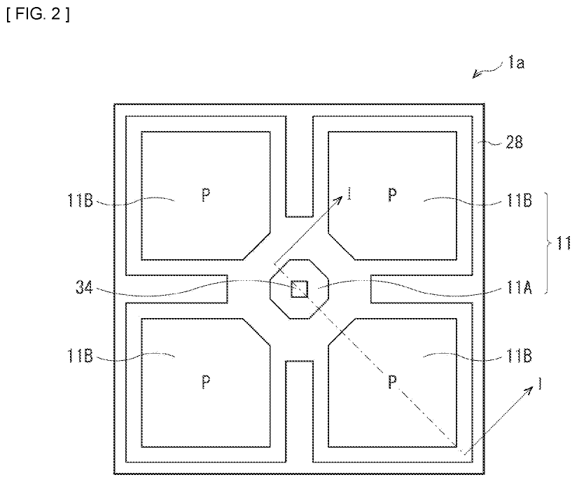

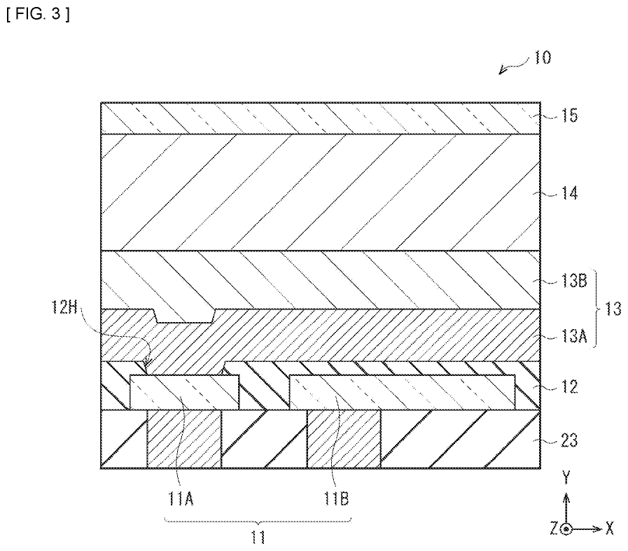

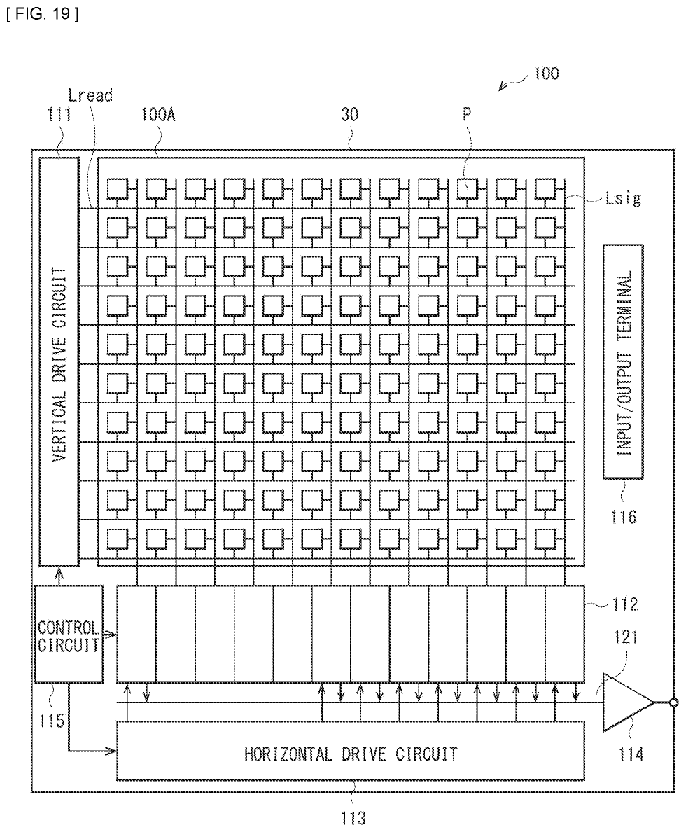

FIG. 1 illustrates a cross-sectional configuration of an imaging element (an imaging element 1A) according to an embodiment of the present disclosure. FIG. 2 schematically illustrates an example of a planar configuration of the imaging element 1A illustrated in FIG. 1, and FIG. 1 illustrates a cross-section taken along a line I-I illustrated in FIG. 2. FIG. 3 is a schematic enlarged view of an example of a cross-sectional configuration of a main portion (a photoelectric converter 10) of the imaging element 1A illustrated in FIG. 1. The imaging element 1A is included, for example, in one of pixels (unit pixels P) that are repeatedly disposed in an array in a pixel section 100A of an imaging device (e.g., an imaging device 1; see FIG. 19) such as a CMOS (Complementary Metal Oxide Semiconductor) image sensor used for an electronic apparatus such as a digital still camera or a video camera. In the pixel section 100A, pixel units 1a are repeatedly disposed as repeating units in an array having a row direction and a column direction. Each of the pixel units 1a includes four unit pixels P that are disposed, for example, in two rows and two columns as illustrated in FIG. 2.

The imaging element 1A according to the present embodiment includes a semiconductor layer 13 between a lower electrode 11 and a photoelectric conversion layer 14 in the photoelectric converter 10 provided on a semiconductor substrate 30. The semiconductor layer 13 has a stacked structure. The lower electrode 11 includes a readout electrode 11A and an accumulation electrode 11B. The semiconductor layer 13 includes, for example, a first layer 13A and a second layer 13B, which are stacked in this order from side of the lower electrode 11. The first layer 13A is formed using an oxide material (a first oxide material) having a carrier concentration of 1E19 cm⁻³ or more and 1E21 cm⁻³ or less and bond dissociation energy of 3.58 eV or more and 5.50 eV or less. The second layer 13B is formed using the first oxide material and an oxide material (a second oxide material) having a band gap of 4.5 eV or more and bond dissociation energy of 4.0 eV or more and 8.8 eV or less. In the present embodiment, the readout electrode 11A corresponds to a specific example of a “second electrode” of the present disclosure, and the accumulation electrode 11B corresponds to a specific example of a “first electrode” of the present disclosure. In addition, the first layer 13A corresponds to a specific example of a “first layer” of the present disclosure, and the second layer 13B corresponds to a specific example of a “second layer” of the present disclosure.

### 1-1. Configuration of Imaging Element

The imaging element 1A is a so-called longitudinal spectral type imaging element in which one photoelectric converter 10 and two photoelectric conversion regions (photoelectric conversion regions 32B and 32R) are stacked in a longitudinal direction. The one photoelectric converter 10 is formed using, for example, an organic material, and the two photoelectric conversion regions (the photoelectric conversion regions 32B and 32R) each include, for example, an inorganic material. The photoelectric converter 10 is provided on side of a back surface (a first surface 30S1) of the semiconductor substrate 30. The photoelectric conversion regions 32B and 32R are formed to be buried in the semiconductor substrate 30 and stacked in a thickness direction of the semiconductor substrate 30.

The photoelectric converter 10 and the photoelectric conversion regions 32B and 32R perform photoelectric conversion by selectively detecting respective pieces of light in different wavelength ranges. For example, the photoelectric converter 10 acquires a color signal of green (G). The photoelectric conversion regions 32B and 32R respectively acquire a color signal of blue (B) and a color signal of red (R) by using a difference between absorption coefficients. This allows the imaging element 1A to acquire a plurality of types of color signals in one pixel without using any color filter.

It is to be noted that, in the imaging element 1A, a case is described where electrons of electron-hole pairs generated through photoelectric conversion are read out as signal electric charges (a case where an n-type semiconductor region serves as a photoelectric conversion layer). In addition, in the drawings, “+ (plus)” attached to “p” and “n” indicates a high p-type or n-type impurity concentration.

The semiconductor substrate 30 includes, for example, an n-type silicon (Si) substrate, and includes a p-well 31 in a predetermined region. A second surface (a front surface of the semiconductor substrate 30) 30S2 of the p-well 31 is provided with, for example, various floating diffusions (floating diffusion layers) FD (e.g., FD1, FD2, and FD3), and various transistors Tr (e.g., a vertical transistor (a transfer transistor) Tr2, a transfer transistor Tr3, an amplifier transistor (a modulation element) AMP, and a reset transistor RST). The second surface 30S2 of the semiconductor substrate 30 is further provided with a multilayer wiring layer 40 with a gate insulating layer 33 interposed therebetween. The multilayer wiring layer 40 has, for example, a configuration in which wiring layers 41, 42, and 43 are stacked in an insulating layer 44. In addition, a peripheral portion of the semiconductor substrate 30 is provided with a peripheral circuit (not illustrated) including a logic circuit and the like.

It is to be noted that FIG. 1 illustrates side of the first surface 30S1 of the semiconductor substrate 30 as a light incident surface S1, and side of the second surface 30S2 thereof as wiring layer side S2.

In the photoelectric converter 10, the semiconductor layer 13 and the photoelectric conversion layer 14 are stacked in this order from side of the lower electrode 11 between the lower electrode 11 and an upper electrode 15 that are disposed to be opposed to each other. In the semiconductor layer 13, the first layer 13A and the second layer 13B are stacked in this order from side of the lower electrode 11. The first layer 13A is formed using the first oxide material having the above-described desired carrier concentration and the above-described desired bond dissociation energy. The second layer 13B is formed using the first oxide material and the second oxide material having the above-described desired band gap and the above-described desired bond dissociation energy. The photoelectric conversion layer 14 includes a p-type semiconductor and an n-type semiconductor, and has a bulk heterojunction structure therein. The bulk heterojunction structure is a p/n junction surface formed by mixing a p-type semiconductor and an n-type semiconductor.

The photoelectric converter 10 further includes an insulating layer 12 between the lower electrode 11 and the semiconductor layer 13. The insulating layer 12 is provided, for example, over the whole of the pixel section 100A, and has an opening 12H on the readout electrode 11A included in the lower electrode 11. The readout electrode 11A is electrically coupled to the first layer 13A of the semiconductor layer 13 through this opening 12H.

It is to be noted that FIG. 1 illustrates an example in which the semiconductor layers 13, the photoelectric conversion layer 14, and the upper electrode 15 are provided, for example, as continuous layers that are common to a plurality of imaging elements 1A, but the semiconductor layer 13, the photoelectric conversion layer 14, and the upper electrode 15 may be separately formed for each of the unit pixels P.

For example, a layer (a fixed electric charge layer) 21 having fixed electric charges, a dielectric layer 22 having an insulation property, and an interlayer insulating layer 23 are provided in this order from side of the first surface 30S1 of the semiconductor substrate 30 between the first surface 30S1 of the semiconductor substrate 30 and the lower electrode 11.

The photoelectric conversion regions 32B and 32R each enable dispersion of light in the longitudinal direction with use of a difference in absorbed light wavelength depending on a depth of light incidence in the semiconductor substrate 30 including an silicon substrate, and each have a pn junction in a predetermined region in the semiconductor substrate 30.

A through electrode 34 is provided between the first surface 30S1 and the second surface 30S2 of the semiconductor substrate 30. The through electrode 34 is electrically coupled to the readout electrode 11A, and the photoelectric converter 10 is coupled to a gate Gamp of the amplifier transistor AMP and one source/drain region 36B of the reset transistor (a reset transistor Tr1rst) also serving as the floating diffusion FD1. This allows the imaging element 1A to favorably transfer electric charges (herein, electrons) generated in the photoelectric converter 10 on side of the first surface 30S1 of the semiconductor substrate 30 to side of the second surface 30S2 of the semiconductor substrate 30, which makes it possible to enhance characteristics.

A lower end of the through electrode 34 is coupled to a coupling section 41A in the wiring layer 41, and the coupling section 41A and the gate Gamp of the amplifier transistor AMP are coupled through a lower first contact 45. The coupling section 41A and the floating diffusion FD1 (a region 36B) are coupled through, for example, a lower second contact 46. An upper end of the through electrode 34 is coupled to the readout electrode 11A through, for example, a pad section 39A and an upper first contact 24A.

A protective layer 51 is provided above the photoelectric converter 10. A wiring line is provided in the protective layer 51. The wiring line electrically couples the upper electrode 15 and a peripheral circuit portion, for example, around a light-shielding film 53 and the pixel section 100A. An optical member such as a planarization layer (not illustrated) or an on-chip lens 52L is further provided above the protective layer 51.

In the imaging element 1A according to the present embodiment, light having entered the photoelectric converter 10 from the light incidence side S1 is absorbed by the photoelectric conversion layer 14. Excitons thereby generated move to an interface between an electron donor and an electron acceptor included in the photoelectric conversion layer 14 and undergo exciton separation. In other words, the excitons are dissociated into electrons and holes. The electric charges (electrons and holes) generated here are transported to different electrodes by diffusion due to a carrier concentration difference and an internal electric field caused by a work function difference between an anode (e.g., the upper electrode 15) and a cathode (e.g., the lower electrode 11). The transported electric charges are detected as photocurrent. In addition, application of a potential between the lower electrode 11 and the upper electrode 15 makes it possible to control transport directions of electrons and holes.

Configurations, materials, and the like of the respective components are described in detail below.

The photoelectric converter 10 is an organic photoelectric conversion element that absorbs, for example, green light corresponding to a portion or the entirety of a selective wavelength range (e.g., 450 nm or more and 650 nm or less) and generates excitons.

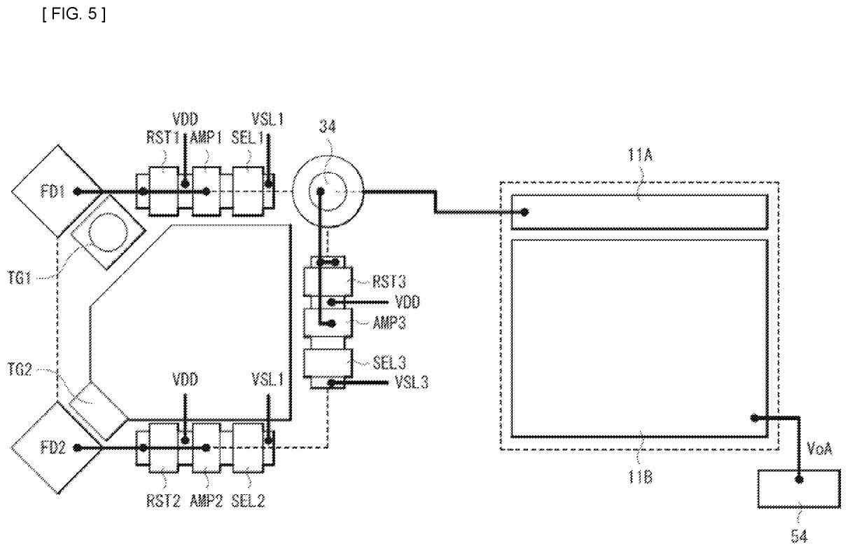

The lower electrode 11 (a cathode) includes, for example, a plurality of electrodes (e.g., two electrodes that are the readout electrode 11A and the accumulation electrode 11B). The readout electrode 11A is for transferring electric charges generated in the photoelectric conversion layer 14 to the floating diffusion FD1. One readout electrode 21A is provided for each pixel unit 1a including four unit pixels P that are disposed, for example, in two rows and two columns. The readout electrode 21A is coupled to the floating diffusion FD1 through, for example, an upper second contact 24B, a pad section 39B, the upper first contact 29A, the pad section 39A, the through electrode 34, the coupling section 41A, and the lower second contact 46. The accumulation electrode 11B is for accumulating, in the semiconductor layer 13, electrons as signal electric charges of the electric charges generated in the photoelectric conversion layer 14. accumulation electrode 11B is provided in a region that is opposed to light receiving surfaces of the photoelectric conversion regions 32B and 32R formed in the semiconductor substrate 30 and covers these light receiving surfaces. It is preferable that the accumulation electrode 11B be larger than the readout electrode 11A. This makes it possible to accumulate more electric charges. As illustrated in FIG. 5, a voltage applying section 54 is coupled to the accumulation electrode 11B through, for example, wiring lines such as an upper third contact 24C and a pad section 39C.

The lower electrode 11 includes an electrically conducive film having light transmissivity. The lower electrode 11 includes, for example, indium tin oxide (ITO). In addition to ITO, a tin oxide (SnO₂)-based material to which a dopant is added or a zinc oxide-based material obtained by adding a dopant to zinc oxide (ZnO) may be used as a material included in the lower electrode 11. Examples of the zinc oxide-based material include aluminum zinc oxide (AZO) to which aluminum (Al) is added as a dopant, gallium zinc oxide (GZO) to which gallium (Ga) is added, and indium zinc oxide (IZO) to which indium (In) is added. In addition, IGZO, ITZO, CuI, InSbO₄, ZnMgO, CuInO₂, MgIN₂O₄, CdO, ZnSnO₃, or the like may also be used in addition to these.

The insulating layer 12 is for electrically separating the accumulation electrode 11B and the semiconductor layer 13. The insulating layer 12 is provided, for example, on the interlayer insulating layer 23 to cover the lower electrode 11. The insulating layer 12 is provided with the opening 12H on the readout electrode 11A of the lower electrode 11, and the readout electrode 11A and the semiconductor layer 13 are electrically coupled through this opening 12H. The insulating layer 12 includes, for example, a single layer film including one kind of silicon oxide (SiOₓ), silicon nitride (SiNₓ), silicon oxynitride (SiON), and the like or a stacked film including two or more kinds of them. The insulating layer 12 has, for example, a thickness of 10 nm or more and 500 nm or less.

The semiconductor layer 13 is for accumulating the electric charges generated by the photoelectric conversion layer 14. As described above, the semiconductor layer 13 is provided between the lower electrode 11 and the photoelectric conversion layer 14. The semiconductor layer 13 has a stacked structure in which the first layer 13A and the second layer 13B are stacked in this order from side of the lower electrode 11. Specifically, the first layer 13A is provided on the insulating layer 12 that electrically separates the lower electrode 11 and the semiconductor layer 13, and is directly electrically coupled to the readout electrode 11A in the opening 12H provided on the readout electrode 11A. The second layer 13B is provided between the first layer 13A and the photoelectric conversion layer 14.

It is possible to form the semiconductor layer 13 using, for example, an oxide semiconductor material. In particular, in the present embodiment, electrons of electric charges generated in the photoelectric conversion layer 14 are used as signal electric charges; therefore, it is possible to form the semiconductor layer 13 using an n-type oxide semiconductor material.

The first layer 13A is for preventing electric charges accumulated in the semiconductor layer 13 from being trapped at an interface with the insulating layer 12 and efficiently transferring the electric charges to the readout electrode 11A. The second layer 13B is for preventing electric charges generated in the photoelectric conversion layer 14 from being trapped at an interface with the photoelectric conversion layer 14 and an interface with the first layer 13A.

It is possible to form the first layer 13A using, for example, the first oxide material having a carrier concentration of 1E19 cm⁻³ or more and 1E21 cm⁻³ or less and bond dissociation energy of 3.58 eV or more. The upper limit of the bond dissociation energy of the first oxide material is, for example, equal to or less than bond dissociation energy (5.50 eV) of Sn—O that are elements included in ITO. It is possible to form the second layer 13B using, for example, the first oxide material and the second oxide material having a band gap of 4.5 eV or more and bond dissociation energy of 4.0 eV or more. The upper limit of the bond dissociation energy of the second oxide material is, for example, equal to or less than bond dissociation energy (8.8 eV) of Ta—O that is a wide band gap material.

The carrier concentration is the number of electric charge carriers in per volume, and depends on position, as with other concentrations. The carrier concentration is obtained by integrating electric charge density over an energy range that electric charges can have. Controlling the carrier concentration within a desired range makes it possible to smoothly accumulate and transfer electric charges in the first layer 13A and the second layer 13B, which makes it possible to achieve high transfer efficiency and reduction in the occurrence of afterimages.

The bond dissociation energy is one measure of bond strength in a chemical bond, and is defined as standard enthalpy change in a case where a certain bond is cleaved by homolysis at 0 K (absolute zero). It is to be noted that homolysis is one form of cleavage of a covalent bond, and indicates a cleavage form such that two electrons (a binding electron pair) forming a covalent bond are distributed one to each of two fragments generated by cleavage. Forming each of the first layer 13A and the second layer 13B using an oxide material having high bond dissociation energy makes it possible to reduce the occurrence of traps of electric charges resulting from elimination of oxygen in the first layer 13A and the second layer 13B. In addition, forming each of the first layer 13A and the second layer 13B using the oxide material having high bond dissociation energy makes it possible to improve heat resistance of each of the first layer 13A and the second layer 13B.

The band gap indicates an energy level (and a energy difference thereof) from the top of a highest energy band (a valence band) occupied by electrons to the bottom of a lowest unoccupied band (a conduction band).

Examples of the first oxide material include indium oxide (In₂O₃) and ITO including one or both of an In—O bond and a Sn—O bond. Examples of the second oxide material include silicon oxide (SiOₓ (SiO₂)) including an Si—O bond, aluminum oxide (Al₂O₃) including an Al—O bond, zirconium oxide (ZrO₂) including a Zr—O bond, hafnium oxide (HfO₂) including a Hf—O bond, a mixture thereof, an oxide thereof, and the like.

The first layer 13A is formed using In₂O₃ or ITO. It is possible to form the first layer 13A for example, as an amorphous layer. This makes it possible to prevent an increase in the carrier concentration of the first layer 13A and achieve low carrier concentration. In addition, it is possible to suppress the occurrence of dangling bonds on a grain boundary in the first layer 13A or at an interface with the insulating layer 12 and further reduce traps as compared with a case where the first layer 13A is formed as a crystal layer.

It is to be noted that it is possible to determine an amorphous layer and a crystal layer by using the presence or absence of a halo ring of a fast Fourier transform (FFT) image of a transmission electron microscope (TEM) image. For example, a TEM has, on the crystal layer, an image having a bright and dark fringe pattern that is caused by interference between a diffracted wave and a transmitted wave from a certain lattice plane of a crystal and corresponds to both intervals of the lattice. This is referred to as lattice fringe. In contrast, no lattice fringe is confirmed in a case of the amorphous layer.

The second layer 13B is formed using In₂O₃ or ITO that includes SiO_{X} (SiO₂), Al₂O₃, ZrO₂, or HfO₂, or a mixture or a composite oxide thereof at a ratio of, for example, 5 at % or more and 70 at % or less. Film quality of the second layer 13B is not limited, and the second layer 13B may be an amorphous layer or a crystal layer.

A material having a high band gap value such as the second oxide material is so-called insulating material because carriers are not movable therein in an atmosphere at normal temperature and normal pressure. In the present embodiment, controlling the addition amount of the second oxide material makes it possible to achieve a desired carrier concentration and desired mobility. The carrier concentration and mobility are controlled by the addition amount of the second oxide material; therefore, characteristics thereof are not dependent on temperature. This allows for stable control.

The first layer 13A has, for example, a thickness of 2 nm or more and 10 nm or less. The second layer 13B has, for example, a thickness of 15 nm or more and 100 nm or less. Although the first layer 13A and the second layer 13B are within the thickness ranges described above, it is preferable that a ratio (t2/t1) of a thickness (t2) of the second layer 13B to a thickness (t1) of the first layer 13A be 4 or more and 8 or less. This allows the second layer 13B to sufficiently absorb carriers generated in the first layer 13A.

The photoelectric conversion layer 14 absorbs, for example, 60% or more of a predetermined wavelength included in at least a range from the visible light region to a near-infrared region to perform electric charge separation. The photoelectric conversion layer 14 absorbs, for example, light of some or all wavelengths in the visible light region and the near-infrared region of 400 nm or more and less than 1300 nm. The photoelectric conversion layer 14 includes, for example, two or more kinds of organic materials each functioning as a p-type semiconductor or an n-type semiconductor, and has a junction surface (p/n junction surface) therein between the p-type semiconductor and the n-type semiconductor. In addition, the photoelectric conversion layer 14 may include a stacked structure (p-type semiconductor layer/n-type semiconductor layer) of a layer including a p-type semiconductor (a p-type semiconductor layer) and a layer including an n-type semiconductor (an n-type semiconductor layer), a stacked structure (p-type semiconductor layer/bulk hetero layer) of a p-type semiconductor layer and a mixed layer (a bulk hetero layer) of a p-type organic semiconductor and an n-type organic semiconductor, or a stacked structure (n-type semiconductor layer/bulk hetero layer) of an n-type semiconductor layer and a bulk hetero layer. In addition, the photoelectric conversion layer 14 may include, only a mixed layer (a bulk hetero layer) of a p-type semiconductor and an n-type semiconductor.

The p-type semiconductor is a hole transport material that relatively functions as an electron donor, and the n-type semiconductor is an electron transport material that relatively functions as an electron acceptor. The photoelectric conversion layer 14 provides a field in which excitons (electron-hole pairs) generated in absorbing light are separated into electrons and holes. Specifically, electron-hole pairs are separated into electrons and holes at an interface (an p/n junction surface) between the electron donor and the electron acceptor.

Examples of the p-type semiconductor include thienoacene-based materials typified by a naphthalene derivative, an anthracene derivative, a phenanthrene derivative, a pyrene derivative, a perylene derivative, a tetracene derivative, a pentacene derivative, a quinacridone derivative, a thiophene derivative, a thienothiophene derivative, a benzothiophene derivative, a benzothienobenzothiophene (BTBT) derivative, a dinaphthothienothiophene (DNTT) derivative, a dianthracenothienothiophene (DATT) derivative, a benzobisbenzothiophene (BBBT) derivative, a thienobisbenzothiophene (TBBT) derivative, a dibenzothienobisbenzothiophene (DBTBT) derivative, a dithienobenzodithiophene (DTBDT) derivative, a dibenzothienodithiophene (DBTDT) derivative, a benzodithiophene (BDT) derivative, a naphthodithiophene (NDT) derivative, an anthracenodithiophene (ADT) derivative, a tetracenodithiophene (TDT) derivative, and a pentacenodithiophene (PDT) derivative. In addition, examples of the p-type semiconductor include a triphenylamine derivative, a carbazole derivative, a picene derivative, a chrysene derivative, for example, a fluoranthene derivative, a phthalocyanine derivative, a subphthalocyanine derivative, a subporphyrazine derivative, a metal complex including a heterocyclic compound as a ligand, a polythiophene derivative, a polybenzothiadiazole derivative, a polyfluorene derivative, and the like.

Examples of the n-type semiconductor include a fullerene and a fullerene derivative typified by higher fullerene, such as fullerere C₆₀, fullerene C₇₀, and fullerene C₇₄, endohedral fullerene, and the like. Examples of a substituent group included in the fullerene derivative include a halogen atom, a straight-chain, branched, or cyclic alkyl group or phenyl group, a group including a straight-chain or condensed aromatic compound, a group including a halide, a partial fluoroalkyl group, a perfluoroalkyl group, a silyl alkyl group, a silyl alkoxy group, an aryl silyl group, an aryl sulfanyl group, an alkyl sulfanyl group, an aryl sulfonyl group, an alkyl sulfonyl group, an aryl sulfide group, an alkyl sulfide group, an amino group, an alkyl amino group, an aryl amino group, a hydroxy group, an alkoxy group, an acyl amino group, an acyloxy group, a carbonyl group, a carboxy group, a carboxamide group, a carboalkoxy group, an acyl group, a sulfonyl group, a cyano group, a nitro group, a group including a chalcogenide, a phosphine group, a phosphone group, and derivatives thereof. Examples of a specific fullerene derivative include fullerene fluoride, a PCBM fullerene compound, a fullerene multimer, and the like. In addition, examples of the n-type semiconductor include an organic semiconductor having a HOMO level and a LUMO level larger (deeper) than those of the p-type organic semiconductor, and an inorganic metal oxide having light transmissivity.

Examples of the n-type organic semiconductor include a heterocyclic compound containing a nitrogen atom, an oxygen atom, or a sulfur atom. Specific examples thereof include organic molecules including, as a part of a molecular framework, a pyridine derivative, a pyrazine derivative, a pyrimidine derivative, a triazine derivative, a quinoline derivative, a quinoxaline derivative, an isoquinoline derivative, an acridine derivative, a phenazine derivative, a phenanthroline derivative, a tetrazole derivative, a pyrazole derivative, an imidazole derivative, a thiazole derivative, an oxazole derivative, an imidazole derivative, a benzimidazol derivative, a benzotriazole derivative, a benzoxazole derivative, a benzoxazole derivative, a carbazole derivative, a benzofuran derivative, a dibenzofuran derivative, a subporphyrazine derivative, a polyphenylene vinylene derivative, a polybenzothiadiazole derivative, a polyfluorene derivative, and the like, an organic metal complex, a subphthalocyanine derivative, a quinacridone derivative, a cyanine derivative, and a merocyanine derivative.

The photoelectric conversion layer 14 may further include an organic material that absorbs light in a predetermined wavelength range and allows light in another wavelength range to pass therethrough, that is, a so-called dye material, in addition to the p-type semiconductor and the n-type semiconductor. In a case where the photoelectric conversion layer 14 is formed using three kinds of organic materials including the p-type semiconductor, the n-type semiconductor, and the dye material, the p-type semiconductor and the n-type semiconductor are preferably materials having light transmissivity in the visible light region. This allows the photoelectric conversion layer 14 to selectively photoelectrically convert light in a wavelength range that is absorbed by the dye material.

The photoelectric conversion layer 14 has, for example, a thickness of 10 nm or more and 500 nm or less, and preferably 100 nm or more and 400 nm or less.

The upper electrode 15 (an anode) includes, for example, an electrically-conductive film having light transmissivity, as with the lower electrode 11. Examples of a material included in the upper electrode 15 include indium tin oxide (ITO) that is In₂O₃ to which tin (Sn) is added as a dopant. An ITO thin film may have high crystallinity or low crystallinity (close to amorphous). In addition to the above-described material, examples of the material included in the lower electrode 11 include a tin oxide (SnO₂)-based material to which a dopant is added, for example, ATO to which Sb is added as a dopant, and FTO to which fluorine is added as a dopant. In addition, zinc oxide (ZnO) or a zinc oxide-based material obtained by adding a dopant may be used. Examples of the ZnO-based material include aluminum zinc oxide (AZO) to which aluminum (Al) is added as a dopant, gallium zinc oxide (GZO) to which gallium (Ga) is added, and indium zinc oxide (IZO) to which indium (In) is added. Furthermore, zinc oxides (IGZO, In—GaZnO₄) to which indium and gallium are added as dopants may be used. In addition, as the material included in the lower electrode 11, CuI, InSbO₄, ZnMgO, CuInO₂, MgIN₂O₄, CdO, ZnSnO₃, TiO₂, or the like may be used, and a spinel oxide or an oxide having a YbFe₂O₄ structure may be used.

It is possible to form the upper electrode 15 as a single layer film or a stacked film including any of the above-described materials. The upper electrode 15 has, for example, a thickness of 20 nm or more and 200 nm or less, preferably 30 nm or more and 150 nm or less.

It is to be noted that, in addition to the semiconductor layer 13 and the photoelectric conversion layer 14, another layer may be further provided between the lower electrode 11 and the upper electrode 15. For example, a buffer layer also serving as an electron blocking film may be provided between the semiconductor layer 13 and the photoelectric conversion layer 14. A buffer layer also serving as a hole blocking film, a work function adjustment layer, and the like may be stacked between the photoelectric conversion layer 14 and the upper electrode 15. In addition, the photoelectric conversion layer 14 may have a pin bulk heterostructure in which, for example, a p-type blocking layer, a layer (an i layer) including a p-type semiconductor and an n-type semiconductor, and an n-type blocking layer are stacked.

The fixed electric charge layer 21 may be a film having positive fixed electric charges or a film having negative fixed electric charges. It is preferable that a semiconductor material or an electrically-conductive material having a wider band gap than that of the semiconductor substrate 30 be used as a material included in the fixed electric charge layer 21. This makes it possible to suppress generation of a dark current at an interface of the semiconductor substrate 30. Examples of the material included in the fixed electric charge layer 21 include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), aluminum oxynitride (AlOₓN_{y}), and the like.

The dielectric layer 22 is for preventing reflection of light caused by a refractive index difference between the semiconductor substrate 30 and the interlayer insulating layer 23. It is preferable that a material included in the dielectric layer 22 be a material having a refractive index between the refractive index of the semiconductor substrate 30 and the refractive index of the interlayer insulating layer 23. Examples of the material included in the dielectric layer 22 include SiOₓ, TEOS, SiNₓ, SiOₓN_{y}, and the like.

The interlayer insulating layer 23 includes, for example, a single layer film including one kind of SiOₓ, SiNₓ, SiOₓN_{y}, and the like or a stacked film including two or more kinds of them.

A shield electrode 28 is provided together with the lower electrode 11 on the interlayer insulating layer 23. The shield electrode 28 is for preventing capacitive coupling between the adjacent pixel units 1a. The shield electrode 28 is provided around the pixel units 1a each including four pixels that are disposed, for example, in two rows and two columns. A fixed potential is applied to the shield electrode 28. The shield electrode 28 further extends between the pixels adjacent in the row direction (Z axis direction) and the column direction (X axis direction) in the pixel unit 1a.

The photoelectric conversion regions 32B and 32R each include, for example, a PIN (Positive Intrinsic Negative) photodiode, and each have a pn junction in a predetermined region in the semiconductor substrate 30. The photoelectric conversion regions 32B and 32R each enable dispersion of light in the longitudinal direction with use of a difference in absorbed wavelength range depending on a depth of light incidence in the silicon substrate.

The photoelectric conversion region 32B selectively detects blue light to accumulate a signal electric charge corresponding to blue. The photoelectric conversion region 32B is formed at a depth that allows the blue light to be photoelectrically converted efficiently. The photoelectric conversion region 32R selectively detects red light to accumulate a signal electric charge corresponding to red. The photoelectric conversion region 32R is formed at a depth that allows the red light to be photoelectrically converted efficiently. It is to be noted that blue (B) is a color corresponding to, for example, a wavelength range of 400 nm or more and less than 495 nm and red (R) is a color corresponding to, for example, a wavelength range of 620 nm or more and less than 750 nm. It is sufficient if each of the photoelectric conversion regions 32B and 32R is able to detect light in a portion or the entirety of the corresponding wavelength range.

Specifically, as illustrated in FIG. 3, the photoelectric conversion region 32B and the photoelectric conversion region 32R each include, for example, a p+ region serving as a hole accumulation layer and an n region serving as an electron accumulation layer (have a p-n-p stacked structure). The n region of the photoelectric conversion region 32B is coupled to the vertical transistor Tr2. The p+ region of the photoelectric conversion region 32B is bent along the vertical transistor Tr2 and leads to the p+ region of the photoelectric conversion region 32R.

The gate insulating layer 33 includes, for example, a single layer film including one kind of SiOₓ, SiNₓ, SiOₓN_{y}, and the like or a stacked film including two or more kinds of them.

The through electrode 34 is provided between the first surface 30S1 and the second surface 30S2 of the semiconductor substrate 30. The through electrode 34 has a function as a connector between the photoelectric converter 10 and each of a gate Gamp of the amplifier transistor AMP and the floating diffusion FD1, and serves as a transmission path for the electric charges generated by the photoelectric converter 10. A reset gate Grst of the reset transistor RST is disposed next to the floating diffusion FD1 (one source/drain region 36B of the reset transistor RST). This allows the reset transistor RST to reset electric charges accumulated in the floating diffusion FD1.

An upper end of the through electrode 34 is coupled to the readout electrode 11A through, for example, the pad section 39A, the upper first contact 24A, the pad electrode 38B, and the upper second contact 24B provided in the interlayer insulating layer 23. A lower end of the through electrode 34 is coupled to the coupling section 41A in the wiring layer 41, and the coupling section 41A and the gate Gamp of the amplifier transistor AMP are coupled through the lower first contact 45. The coupling section 41A and the floating diffusion FD1 (the region 36B) are coupled through, for example, the lower second contact 46.

It is possible to form the upper first contact 24A, the upper second contact 24B, the upper third contact 24C, the pad sections 39A, 39B, and 39C, the wiring layers 41, 42, and 43, the lower first contact 45, the lower second contact 46, and a gate wiring layer 47 by using, for example, a doped silicon material such as PDAS (Phosphorus Doped Amorphous Silicon) or a metal material such as Al, W, Ti, Co, Hf, and Ta.

The insulating layer 44 includes, for example, a single layer film including one kind of SiOₓ, SiNₓ, SiOₓN_{y}, and the like or a stacked film including two or more kinds of them.

The protective layer 51 and the on-chip lens 52L each include a material having light transmissivity, and each include, for example, a single layer film including one kind of SiOₓ, SiNₓ, SiOₓN_{y}, and the like or a stacked film including two or more kinds of them. The protective layer 51 has, for example, a thickness of 100 nm or more and 30000 nm or less.

The light-shielding film 53 is provided not to overlap with at least the accumulation electrode 11B, but to cover a region of the readout electrode 21A that is in direct contact with the semiconductor layer 18. It is possible to form the light-shielding film 53 using, for example, W, Al, an alloy of Al and Cu, and the like.

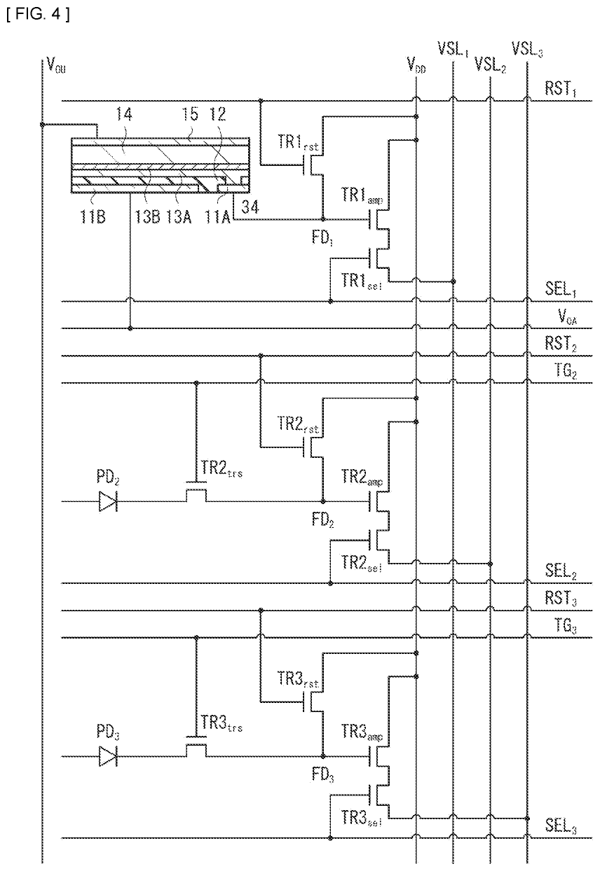

FIG. 4 is an equivalent circuit diagram of the imaging element 1A illustrated in FIG. 1. FIG. 5 schematically illustrates disposition of the lower electrode 11 and a transistor included in a controller in the imaging element 1A illustrated in FIG. 1.

The reset transistor RST (the reset transistor TR1rst) is for resetting electric charges transferred from the photoelectric converter 10 to the floating diffusion FD1, and includes, for example, a MOS transistor. Specifically, the reset transistor TR1rst includes the reset gate Grst, a channel formation region 36A, and source/drain regions 36B and 36C. The reset gate Grst is coupled to a reset line RST1. The one source/drain region 36B of the reset transistor TR1rst also serves as the floating diffusion FD1. The other source/drain region 36C included in the reset transistor TR1rst is coupled to a power supply line VDD.

The amplifier transistor AMP is a modulation element that modulates, to a voltage, the amount of electric charges generated by the photoelectric converter 10, and includes, for example, a MOS transistor. Specifically, the amplifier transistor AMP includes the gate Gamp, a channel formation region 35A, and the source/drain regions 35B and 35C. The gate Gamp is coupled to the readout electrode 11A and the one source/drain region 36B (the floating diffusion FD1) of the reset transistor TR1rst through the lower first contact 45, the coupling section 41A, the lower second contact 46, the through electrode 34, and the like. In addition, the one source/drain region 35B shares a region with the other source/drain region 36C included in the reset transistor TR1rst, and is coupled to the power supply line VDD.

A selection transistor SEL (a selection transistor TR1sel) includes a gate Gsel, a channel formation region 34A, and source/drain regions 34B and 34C. The gate Gsel is coupled to a selection line SEL1. One source/drain region 34B shares a region with the other source/drain region 35C included in the amplifier transistor AMP, and the other source/drain region 34C is coupled to a signal line (a data output line) VSL1.

The transfer transistor TR2 (a transfer transistor TR2trs) is for transferring, to the floating diffusion FD2, the signal electric charge corresponding to blue that has been generated and accumulated in the photoelectric conversion region 32B. The photoelectric conversion region 32B is formed at a deep position from the second surface 30S2 of the semiconductor substrate 30, and it is thus preferable that the transfer transistor TR2trs of the photoelectric conversion region 32B include a vertical transistor. The transfer transistor TR2trs is coupled to a transfer gate line TG2. The floating diffusion FD2 is provided in a region 37C near a gate Gtrs2 of the transfer transistor TR2trs. The electric charge accumulated in the photoelectric conversion region 32B is read out to the floating diffusion FD2 through a transfer channel formed along the gate Gtrs2.

The transfer transistor TR3 (a transfer transistor TR3trs) is for transferring, to the floating diffusion FD3, the signal electric charge corresponding to red that has been generated and accumulated in the photoelectric conversion region 32R. The transfer transistor TR3 (the transfer transistor TR3trs) includes, for example, a MOS transistor. The transfer transistor TR3trs is coupled to a transfer gate line TG3. The floating diffusion FD3 is provided in a region 38C near a gate Gtrs3 of the transfer transistor TR3trs. The electric charge accumulated in the photoelectric conversion region 32R is read out to the floating diffusion FD3 through a transfer channel formed along the gate Gtrs3.

A reset transistor TR2rst, an amplifier transistor TR2amp, and a selection transistor TR2sel included in a controller of the photoelectric conversion region 32B are further provided on side of the second surface 30S2 of the semiconductor substrate 30. A reset transistor TR3rst, an amplifier transistor TR3amp, and a selection transistor TR3sel included in a controller of the photoelectric conversion region 32R are further provided.

The reset transistor TR2rst includes a gate, a channel formation region, and source/drain regions. The gate of the reset transistor TR2rst is coupled to a reset line RST2 and one source/drain region of the reset transistor TR2rst is coupled to the power supply line VDD. Another source/drain region of the reset transistor TR2rst also serves as the floating diffusion FD2.

The amplifier transistor TR2amp includes a gate, a channel formation region, and source/drain regions. The gate is coupled to the other source/drain region (the floating diffusion FD2) of the reset transistor TR2rst. One source/drain region included in the amplifier transistor TR2amp shares a region with the one source/drain region included in the reset transistor TR2rst and is coupled to the power supply line VDD.

The selection transistor TR2sel includes a gate, a channel formation region, and source/drain regions. The gate is coupled to a selection line SEL2. One source/drain region included in the selection transistor TR2sel shares a region with another source/drain region included in the amplifier transistor TR2amp. Another source/drain region included in the selection transistor TR2sel is coupled to a signal line (a data output line) VSL2.

The reset transistor TR3rst includes a gate, a channel formation region, and source/drain regions. The gate of the reset transistor TR3rst is coupled to a reset line RST3, and one source/drain region included in the reset transistor TR3rst is coupled to the power supply line VDD. Another source/drain region included in the reset transistor TR3rst also serves as the floating diffusion FD3.

The amplifier transistor TR3amp includes a gate, a channel formation region, and source/drain regions. The gate is coupled to the other source/drain region (the floating diffusion FD3) included in the reset transistor TR3rst. One source/drain region included in the amplifier transistor TR3amp shares a region with the one source/drain region included in the reset transistor TR3rst, and is coupled to the power supply line VDD.

The selection transistor TR3sel includes a gate, a channel formation region, and source/drain regions. The gate is coupled to a selection line SEL3. One source/drain region included in the selection transistor TR3sel shares a region with the other source/drain region included in the amplifier transistor TR3amp. Another source/drain region included in the selection transistor TR3sel is coupled to a signal line (a data output line) VSL3.

The reset lines RST1, RST2, and RST3, the selection lines SEL1, SEL2, and SEL3, and the transfer gate lines TG2 and TG3 are each coupled to a vertical drive circuit included in a drive circuit. The signal lines (the data output lines) VSL1, VSL2, and VSL3 are coupled to a column signal processing circuit 112 included in the drive circuit.

### 1-2. Method of Manufacturing Imaging Element

It is possible to manufacture the imaging element 1A according to the present embodiment, for example, as follows.

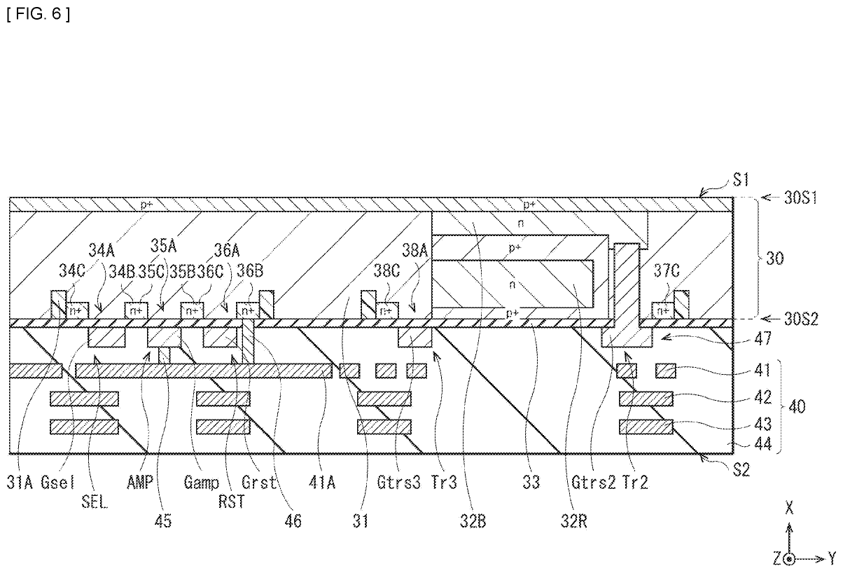

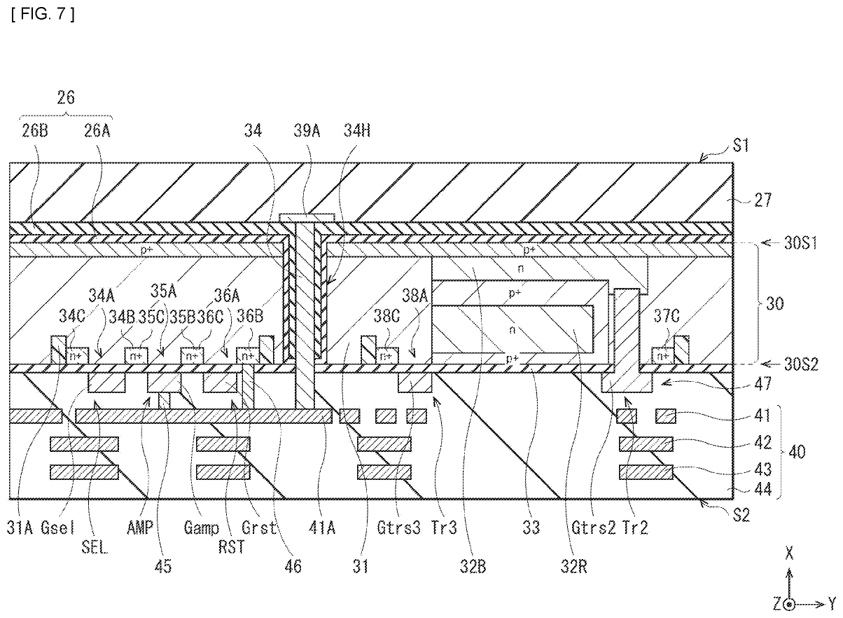

FIGS. 6 to 11 illustrate a method of manufacturing the imaging element 1A in order of processes. First, as illustrated in FIG. 7, for example, the p-well 31 is formed in the semiconductor substrate 30. For example, the n-type photoelectric conversion regions 32B and 32R are formed in this p-well 31. A p+ region is formed near the first surface 30S1 of the semiconductor substrate 30.

As also illustrated in FIG. 6, for example, n+ regions that serve as the floating diffusions FD1 to FD3 are formed on the second surface 30S2 of the semiconductor substrate 30, and the gate insulating layer 33 and the gate wiring layer 47 are then formed. The gate wiring layer 47 includes the respective gates of the transfer transistor Tr2, the transfer transistor Tr3, the selection transistor SEL, the amplifier transistor AMP, and the reset transistor RST. Thus, the transfer transistor Tr2, the transfer transistor Tr3, the selection transistor SEL, the amplifier transistor AMP, and the reset transistor RST are formed. Further, the multilayer wiring layer 40 is formed on the second surface 30S2 of the semiconductor substrate 30. The multilayer wiring layer 40 includes the wiring layers 41 to 43 and the insulating layer 44. The wiring layers 41 to 43 include the lower first contact 45, the lower second contact 46, and the coupling section 41A.

As a base of the semiconductor substrate 30, for example, an SOI (Silicon on Insulator) substrate is used in which the semiconductor substrate 30, a buried oxide film (not illustrated), and a holding substrate (not illustrated) are stacked. Although not illustrated in FIG. 6, the buried oxide film and the holding substrate are joined to the first surface 30S1 of the semiconductor substrate 30. After ion implantation, annealing treatment is performed.

Next, a support substrate (not illustrated), another semiconductor base, or the like is joined onto the multilayer wiring layer 40 provided on side of the second surface 30S2 of the semiconductor substrate 30 and flipped vertically. Thereafter, the semiconductor substrate 30 is separated from the buried oxide film and the holding substrate of the SOI substrate to expose the first surface 30S1 of the semiconductor substrate 30. It is possible to perform the processes described above with technology used in a normal CMOS process including ion implantation, a CVD (Chemical Vapor Deposition) method, and the like.

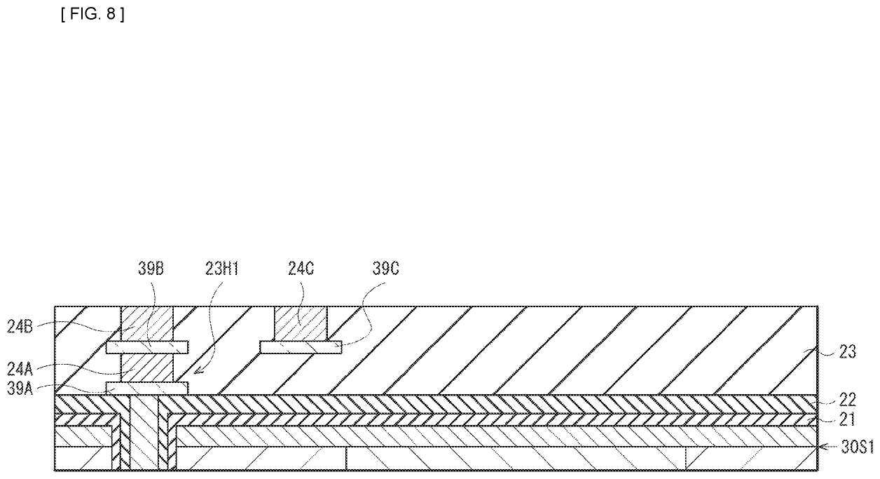

Next, as illustrated in FIG. 7, the semiconductor substrate 30 is processed from side of the first surface 30S1, for example, by dry etching to form, for example, an annular opening 34H. The depth of the opening 34H penetrates from the first surface 30S1 to the second surface 30S2 of the semiconductor substrate 30 and reaches, for example, the coupling section 41A, as illustrated in FIG. 8.

Thereafter, for example, the negative fixed electric charge layer 21 and the dielectric layer 22 are formed in order on the first surface 30S1 of the semiconductor substrate 30 and a side surface of the opening 34H. It is possible to form the fixed electric charge layer 21 by forming a HfOₓ film with use of, for example, an atomic layer deposition method (ALD method). It is possible to form the dielectric layer 22 by forming a SiOₓ film with use of, for example, a plasma CVD method. Next, the pad section 39A is formed at a predetermined position on the dielectric layer 22. In the pad section 39A, a barrier metal including, for example, a stacked film (a Ti/TiN film) of titanium and titanium nitride and a W film are stacked. After that, the interlayer insulating layer 23 is formed on the dielectric layer 22 and the pad section 39A, and a surface of the interlayer insulating layer 23 is planarized with use of a CMP (Chemical Mechanical Polishing) method.

Thereafter, as illustrated in FIG. 8, an opening 23H1 is formed above the pad section 39A. After that, the opening 23H1 is filled with, for example, an electrically-conductive material such as Al to form the upper first contact 24A. Next, as illustrated in FIG. 8, the pad sections 39B and 39C are formed as with the pad section 39A, and then the interlayer insulating layer 23, and the upper second contact 24B and the upper third contact 24C are formed in order.

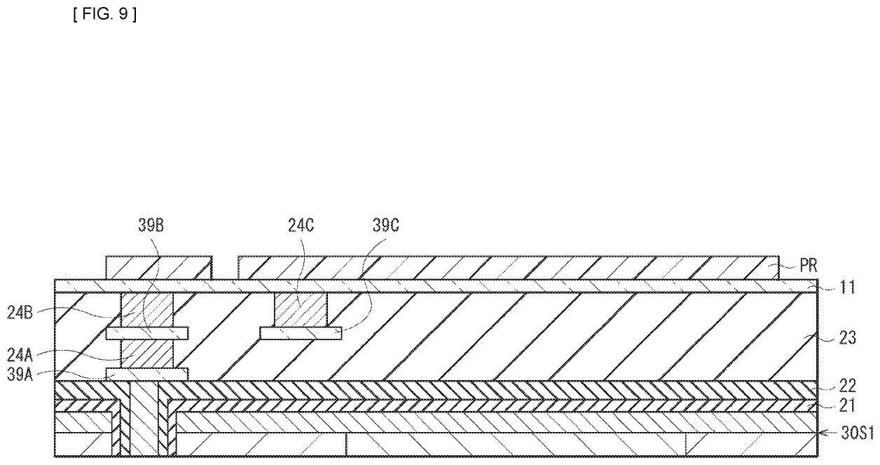

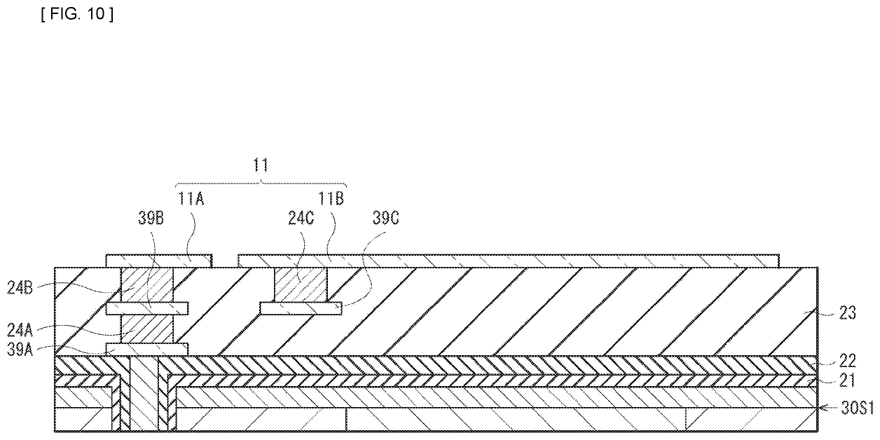

Thereafter, as illustrated in FIG. 9, an electrically-conductive film 11X is formed on the interlayer insulating layer 23 with use of, for example, a sputtering method, and patterning is then performed with use of photolithography technology. Specifically, a photoresist PR is formed at a predetermined position in the electrically-conductive film 11X, and the electrically-conductive film 11X is then processed with use of dry etching or wet etching. After that, the readout electrode 11A and the accumulation electrode 11B are formed as illustrated in FIG. 10 by removing the photoresist PR.

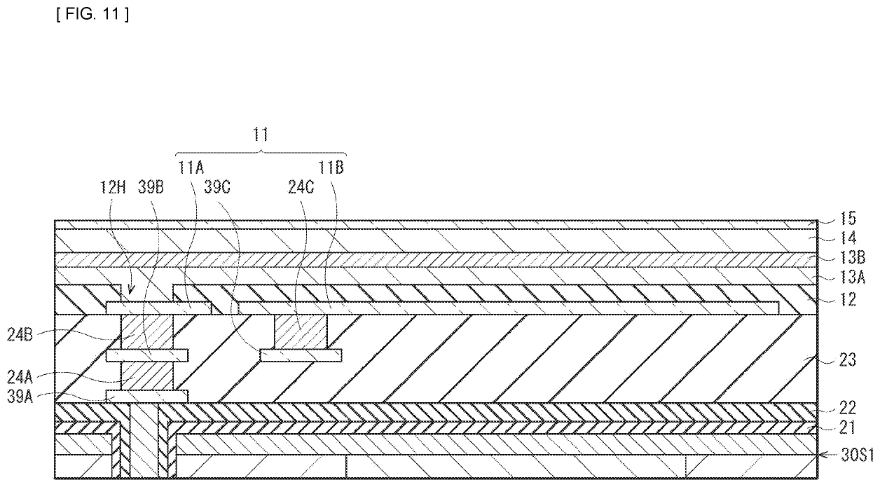

Next, as illustrated in FIG. 11, the insulating layer 12, the semiconductor layer 13 (the first layer 13A and the second layer 13B), the photoelectric conversion layer 14, and the upper electrode 15 are formed in order. For example, a SiOₓ film is formed for the insulating layer 12 with use of, for example, an ALD method. After that, a surface of the insulating layer 12 is planarized with use of a CMP method. After that, the opening 12H is formed on the readout electrode 11A with use of, for example, wet etching. It is possible to form the semiconductor layer 13 with use of, for example, a sputtering method. The photoelectric conversion layer 14 is formed with use of, for example, a vacuum deposition method. The upper electrode 15 is formed with use of, for example, a sputtering method, as with the lower electrode 11. Finally, the protective layer 51, the light-shielding film 53, and the on-chip lens 52L are provided on the upper electrode 15. Thus, the imaging element 1A illustrated in FIG. 1 is completed.

It is to be noted that it is possible to form organic layers such as the photoelectric conversion layer 14, and electrically conductive films such as the lower electrode 11 and the upper electrode 15 with use of a dry film formation method or a wet film formation method. Examples of the dry film formation method include an electron beam (EB) deposition method, various sputtering methods (a magnetron sputtering method, an RF-DC coupled bias sputtering method, an ECR sputtering method, a facing-target sputtering method, and a high frequency sputtering method), an ion plating method, a laser ablation method, a molecular beam epitaxy method, and a laser transfer method, in addition to a vacuum deposition method using resistance heating or high frequency heating. In addition, examples of the dry film formation method include chemical vapor deposition methods such as a plasma CVD method, a thermal CVD method, an MOCVD method, and an optical CVD method. Examples of the wet film formation method include a spin coating method, an ink jet method, a spray coating method, a stamping method, a micro contact printing method, a flexographic printing method, an offset printing method, a gravure printing method, a dipping method, and the like.

As patterning, it is possible to use, in addition to photolithography technology, chemical etching such as a shadow mask and laser transfer, physical etching by ultraviolet light or laser, or the like. As planarization technology, it is possible to use a laser planarization method, a reflow method, or the like in addition to the CMP method.

### 1-4. Signal Acquisition Operation of Imaging Element

In a case where light enters the photoelectric converter 10 through the on-chip lens 52L in the imaging element 1A, the light passes through the photoelectric converter 10 and the photoelectric conversion regions 32B and 32R in this order. While the light passes through the photoelectric converter 10 and the photoelectric conversion regions 32B and 32R, the light is photoelectrically converted for each of green light, blue light, and red light. The following describes operations of acquiring signals of the respective colors.

### (Acquisition of Green Color Signal by Photoelectric Converter 10)

First, green light (G) of the light having entered the imaging element 1A is selectively detected (absorbed) and photoelectrically converted by the photoelectric converter 10.

The photoelectric converter 10 is coupled to the gate Gamp of the amplifier transistor AMP and the floating diffusion FD1 through the through electrode 34. Thus, electrons of excitons generated by the photoelectric converter 10 are taken out from side of the lower electrode 11, transferred to side of the second surface 30S2 of the semiconductor substrate 30 through the through electrode 34, and accumulated in the floating diffusion FD1. At the same time, the amplifier transistor AMP modulates the amount of electric charges generated by the photoelectric converter 10 to a voltage.

In addition, the reset gate Grst of the reset transistor RST is disposed next to the floating diffusion FD1. This causes the reset transistor RST to reset the electric charges accumulated in the floating diffusion FD1.

The photoelectric converter 10 is coupled not only to the amplifier transistor AMP, but also to the floating diffusion FD1 through the through electrode 34, which allows the reset transistor RST to easily reset the electric charges accumulated in the floating diffusion FD1.

In contrast, in a case where the through electrode 34 and the floating diffusion FD1 are not coupled, it is difficult to reset the electric charges accumulated in the floating diffusion FD1, which causes the electric charges to be drawn to side of the upper electrode 15 by application of a large voltage. This may damage the photoelectric conversion layer 24. In addition, a structure that allows for resetting in a short period of time causes an increase in dark time noise, thereby resulting in a trade-off; therefore, this structure is difficult.

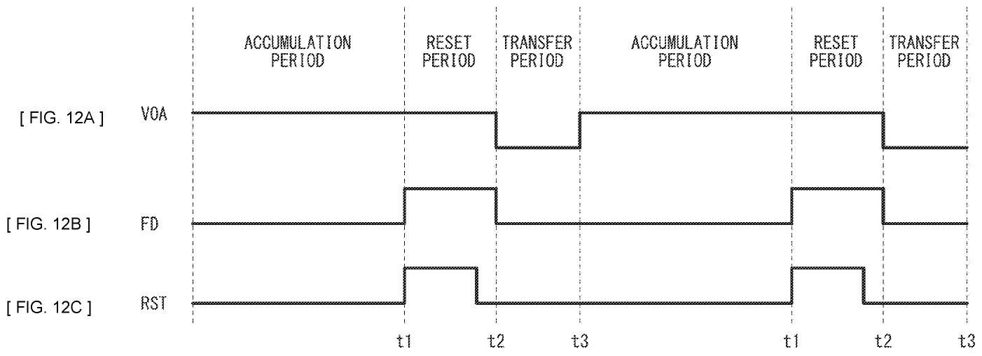

FIG. 12 illustrates an operation example of the imaging element 1A, where (A) indicates a potential at the accumulation electrode 11B, (B) indicates a potential at the floating diffusion FD1 (the readout electrode 11A), and (C) indicates a potential at the gate (Gsel) of the reset transistor TR1rst. In the imaging element 1A, voltages are individually applied to the readout electrode 11A and the accumulation electrode 11B.

In the imaging element 1A, the drive circuit applies a potential V1 to the readout electrode 11A and applies a potential V2 to the accumulation electrode 11B in an accumulation period. Here, it is assumed that the potentials V1 and V2 satisfy V2>V1. This causes electric charges (signal electric charges; electrons) generated through photoelectric conversion to be drawn to the accumulation electrode 11B and accumulated in a region of the semiconductor layer 13 opposed to the accumulation electrode 11B (accumulation period). Additionally, the value of the potential in the region of the semiconductor layer 13 opposed to the accumulation electrode 11B becomes more negative with the passage of time of photoelectric conversion. It is to be noted that holes are sent from the upper electrode 15 to the drive circuit.

In the imaging element 1A, a reset operation is performed in the latter half of the accumulation period. Specifically, at a timing t1, a scanning section changes the voltage of a reset signal RST from a low level to a high level. This turns on the reset transistor TR1rst in the unit pixel P. As a result, the voltage of the floating diffusion FD1 is set to a power supply voltage and the voltage of the floating diffusion FD1 is reset (reset period).

After the reset operation is completed, electric charges are read out. Specifically, the drive circuit applies a potential V3 to the readout electrode 11A and applies a potential V4 to the accumulation electrode 11B at a timing t2. Here, it is assumed that the potentials V3 and V4 satisfy V3<V4. This causes the electric charges accumulated in a region corresponding to the accumulation electrode 11B to be read out from the readout electrode 11A to the floating diffusion FD1. In other words, the electric charges accumulated in the semiconductor layer 13 are read out to the controller (transfer period).

The drive circuit applies the potential V1 to the readout electrode 11A and applies the potential V2 to the accumulation electrode 11B again after the readout operation is completed. This causes electric charges generated through photoelectric conversion to be drawn to the accumulation electrode 11B and accumulated in a region of the photoelectric conversion layer 24 opposed to the accumulation electrode 11B (accumulation period).

### (Acquisition of Blue Color Signal and Red Color Signal by Photoelectric Conversion Regions 32B and 32R)

Thereafter, blue light (B) and red light (R) of the light having passed through the photoelectric converter 10 are respectively absorbed and photoelectrically converted in order by the photoelectric conversion region 32B and the photoelectric conversion region 32R. In the photoelectric conversion region 32B, electrons corresponding to the incident blue light (B) are accumulated in the n region of the photoelectric conversion region 32B and the accumulated electrons are transferred to the floating diffusion FD2 by the transfer transistor Tr2. Similarly, in the photoelectric conversion region 32R, electrons corresponding to the incident red light (R) are accumulated in the n region of the photoelectric conversion region 32R and the accumulated electrons are transferred to the floating diffusion FD3 by the transfer transistor Tr3.

### 1-4. Workings and Effects

In the imaging element 1A according to the present embodiment, the photoelectric converter 10 includes the semiconductor layer 13 provided between the lower electrode 11 and the photoelectric conversion layer 14. In the semiconductor layer 13, the first layer 13A and the second layer 13B are stacked in this order from side of the lower electrode 11. The lower electrode 11 includes the readout electrode 11A and the accumulation electrode 11B. The first layer 13A is formed using the first oxide material having a carrier concentration of 1E19 cm⁻³ or more and 1E21 cm⁻³ or less and bond dissociation energy of 3.58 eV or more and 5.50 eV or less. The second layer 13B is formed using the first oxide material and the second oxide material having a band gap of 4.5 eV or more and bond dissociation energy of 4.0 eV or more and 8.8 eV or less. This is described below.

In recent years, a stacked imaging element in which a plurality of photoelectric converters is stacked in the longitudinal direction has been developed as an imaging element included in a CCD image sensor, a CMOS image sensor, or the like. The stacked imaging element has a configuration in which two photoelectric conversion regions each including a photodiode (PD) are stacked in, for example, a silicon (Si) substrate and a photoelectric converter including a photoelectric conversion layer that includes an organic material is provided above the Si substrate.

In the stacked imaging element, a structure is necessary that accumulates and transfers signal electric charges generated by each of the photoelectric converters. In the photoelectric converter, for example, of a pair of electrodes disposed to be opposed to each other with the photoelectric conversion layer interposed in between, the electrode on photoelectric conversion region side includes two electrodes including a first electrode and an electrode for electric charge accumulation. This makes it possible to accumulate signal electric charges generated by the photoelectric conversion layer. Such an imaging element temporarily accumulates signal electric charges above the electrode for electric charge accumulation and then transfers the signal electric charges to the floating diffusion FD in the Si substrate. This makes it possible to fully deplete an electric charge accumulation section and erase electric charges at the start of exposure. As a result, it is possible to suppress the occurrence of a phenomenon such as an increase in kTC noise, deterioration of random noise, and a decrease in image quality in imaging.

In addition, an imaging element that includes a composite oxide layer including IGZO between the first electrode including the electrode for electric charge accumulation and the photoelectric conversion layer as described above to achieve an improvement in photoresponsivity is developed as an imaging element including a plurality of electrodes on photoelectric conversion region side as described above. However, a composite oxide layer including IGZO includes an oxygen vacancy and a trap that deteriorates high-speed transfer of excess oxygen or the like and afterimage characteristics. An imaging element that includes a semiconductor layer having a stacked structure formed using different kinds of materials has an issue that a trap that occurs at an interface between two layers included in the semiconductor layer becomes a transfer barrier.

In addition, a layer including many oxide semiconductors such as IGZO has inferior film quality, and is therefore desired to be subjected to high-temperature film formation or heat treatment at high temperature. Accordingly, the layer has a low degree of freedom of material selection, and it is difficult to use a material having high characteristics. A layer formed at low temperature has such inferior film quality, and therefore has low heat resistance. The layer formed at low temperature has an issue that characteristics thereof are varied by additional heat treatment or the like.

In contrast, in the present embodiment, of the semiconductor layer 13 that is provided between the lower electrode 11 and the photoelectric conversion layer 14 and includes the first layer 13A and the second layer 13B stacked in this order from side of the lower electrode 11, the first layer 13A is formed using the first oxide material having a carrier concentration of 1E19 cm⁻³ or more and 1E21 cm⁻³ or less and bond dissociation energy of 3.58 eV or more and 5.50 eV or less. The second layer 13B is formed using the first oxide material included in the first layer 13A and the second oxide material having a band gap of 4.5 eV or more and bond dissociation energy of 4.0 eV or more and 8.8 eV or less.

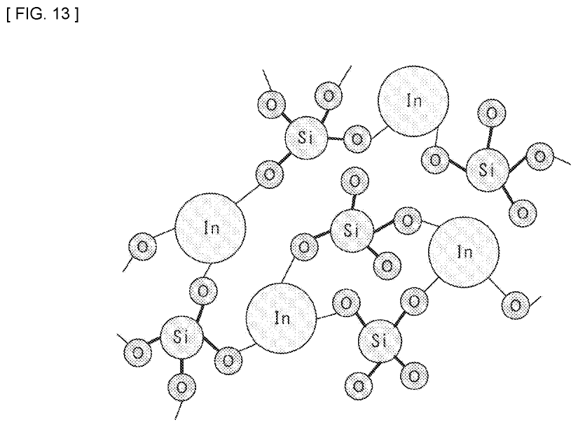

FIG. 13 schematically illustrates, for example, an elemental composition in a layer in a case where the second layer 13B is formed using In₂O₃—SiO. In the second layer 13B, the first oxide material (In₂O₃ in FIG. 4) that is to be crystallized at low temperature serves as a mother skeleton, and the second oxide material (SiO in FIG. 4) is present in the first oxide material. The second oxide material has a high band gap value, and is a so-called insulating material because carriers are not movable therein in an atmosphere at normal temperature and normal pressure. Low-temperature film formation of the second oxide material such as SiO is possible, and the second oxide material has high thermal stability. In addition, the second oxide material also has high bond dissociation energy. Accordingly, adding the second oxide material makes it possible to form a layer having a small defect amount. In addition, it is possible to form an In₂O₃ layer (the second layer 13B) to which the second oxide material is added at a relatively low oxygen concentration, which makes it possible to reduce excess oxygen included in the layer. This reduces the occurrence of traps, and improves heat resistance.

As described above, in the imaging element 1A according to the present embodiment, electric charges generated in the photoelectric conversion layer 14 to stagnate at an interface between the photoelectric conversion layer 14 and the semiconductor layer 13 are reduced, and electric charges move well in the semiconductor layer 13. This makes it possible to improve transfer characteristics and afterimage characteristics.

In addition, in the imaging element 1A according to the present embodiment, the first layer 13A and the second layer 13B are formed using the oxide materials described above, which makes it possible to obtain superior film quality even in a case where these layers are formed at low temperature. In addition, heat resistance is also improved, which makes it possible to prevent variation in characteristics caused by additional heat treatment or the like.

Next, description is given of modification examples 1 to 5 of the present disclosure. It is to be noted that components similar to those in the embodiment described above are denoted by same reference numerals, and description thereof is omitted as appropriate.

### 2. Modification Examples

### 2-1. Modification Example 1

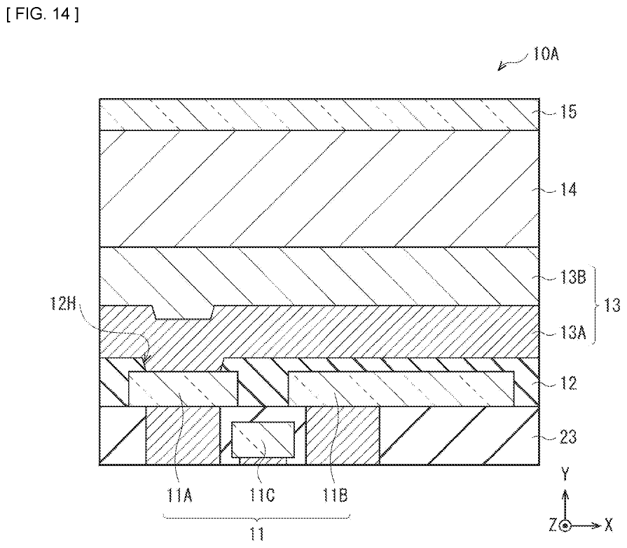

FIG. 14 schematically illustrates a cross-sectional configuration of a main portion (a photoelectric converter 10A) of an imaging element according to the modification example 2 of the present disclosure. The photoelectric converter 10A according to the present modification example is different from the embodiment described above in that a transfer electrode 11C is provided between the readout electrode 11A and the accumulation electrode 11B.

The transfer electrode 11C is for improving efficiency of transferring electric charges accumulated above the accumulation electrode 11B to the readout electrode 11A. The transfer electrode 11C is provided between the readout electrode 11A and the accumulation electrode 11B. Specifically, the transfer electrode 11C is formed, for example, in a layer lower than a layer provided with the readout electrode 11A and the accumulation electrode 11B. The transfer electrode 11C is provided to cause a portion thereof to overlap with the readout electrode 11A and the accumulation electrode 11B.

It is possible to independently apply respective voltages to the readout electrode 11A, the accumulation electrode 11B, and the transfer electrode 11C. In the present modification example, the drive circuit applies a potential V5 to the readout electrode 11A, applies a potential V6 to the accumulation electrode 11B, and applies a potential V7 (V5>V6>V7) to the transfer electrode 11C in a transfer period following the completion of the reset operation. This causes the electric charges accumulated above the accumulation electrode 11B to move from the accumulation electrode 11B onto the transfer electrode 11C and the readout electrode 11A in this order and be read out to the floating diffusion FD1.

In the present modification example, the transfer electrode 11C is provided between the readout electrode 11A and the accumulation electrode 11B in such a manner. This makes it possible to move electric charges from the readout electrode 11A to the floating diffusion FD1 more reliably. Accordingly, it is possible to further improve transfer characteristics and afterimage characteristics.

It is to be noted that in the present modification example, an example has been described in which a plurality of electrodes included in the lower electrode 11 includes three electrodes including the readout electrode 11A, the accumulation electrode 11B, and the transfer electrode 11C. In addition, there may be, however, provided four or more electrodes including a discharge electrode and the like.

### 2-2. Modification Example 2

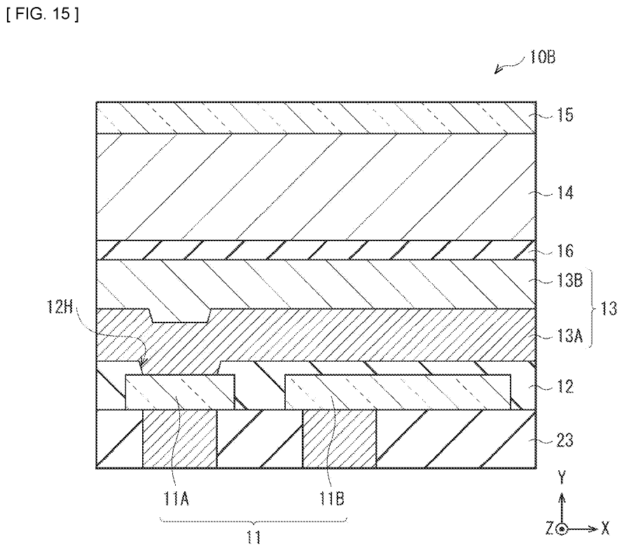

FIG. 15 schematically illustrates a cross-sectional configuration of a main portion (a photoelectric converter 10B) of an imaging element according to the modification example 2 of the present disclosure. The photoelectric converter 10B according to the present modification example is different from the embodiment described above in that a protective layer 16 is provided between the semiconductor layer 13 and the photoelectric conversion layer 14.

The protective layer 16 is for preventing oxygen from being eliminated from an oxide semiconductor material included in the semiconductor layer 13. Examples of a material included in the protective layer 16 include titanium oxide (TiO₂), titanium silicide oxide (TiSiO), niobium oxide (Nb₂O₅), TaOₓ, and the like. It is effective in a case where the protective layer 16 has, for example, one atomic layer as the thickness thereof. It is preferable that the protective layer 16 have, for example, a thickness of 0.5 nm or more and 10 nm or less.

In the present modification example, the protective layer 16 is provided between the semiconductor layer 13 and the photoelectric conversion layer 14 in such a manner. This makes it possible to further reduce elimination of oxygen from the surface of the semiconductor layer 13. This further reduces the occurrence of traps at the interface between the semiconductor layer 13 (specifically, the second layer 13B) and the photoelectric conversion layer 14. In addition, it is possible to prevent signal electric charges (electrons) from flowing back to the photoelectric conversion layer 14 from side of the semiconductor layer 13. This makes it possible to further improve the afterimage characteristics and reliability.

In addition, the present modification example may be combined with the modification example 1 described above.

Furthermore, the present technology is applicable to an imaging element having the following configuration.

### 2-3. Modification Example 3

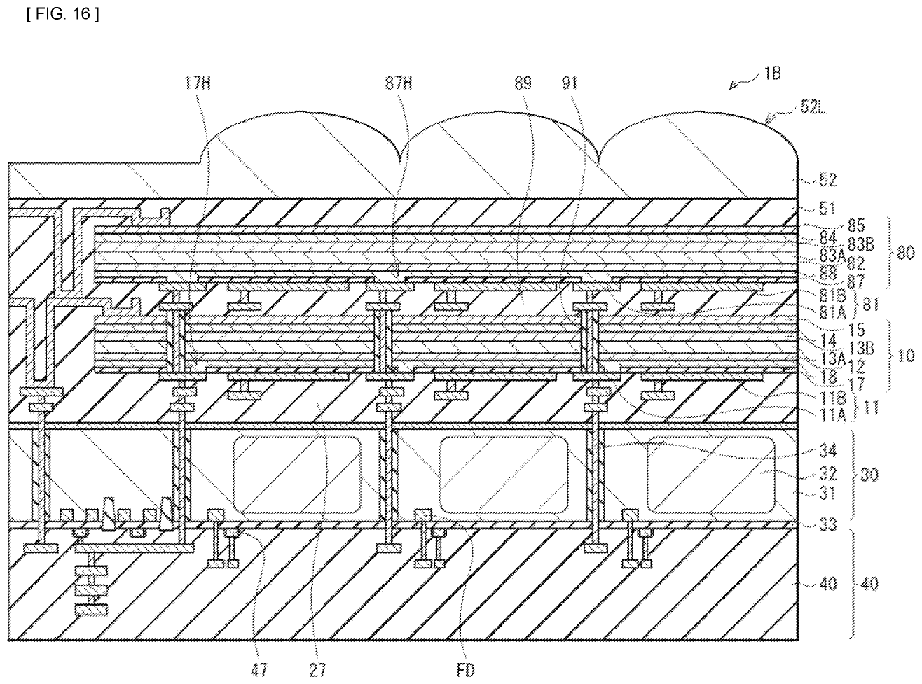

FIG. 16 schematically illustrates a cross-sectional configuration of an imaging element 1B according to the modification example 3 of the present disclosure. The imaging element 1B is, for example, an imaging element such as a CMOS image sensor used for an electronic apparatus such as a digital still camera or a video camera, as with the imaging element 1A according to the embodiment described above. The imaging element 1B according to the present modification example includes two photoelectric converters 10 and 80, and one photoelectric conversion region 32 that are stacked in the longitudinal direction.

The photoelectric converters 10 and 80 and the photoelectric conversion region 32 perform photoelectric conversion by selectively detecting respective pieces of light in different wavelength ranges. For example, the photoelectric converter 10 acquires a color signal of green (G). For example, the photoelectric converter 80 acquires a color signal of blue (B). For example, the photoelectric conversion region 32 acquires a color signal of red (R). This allows the imaging element 1B to acquire a plurality of types of color signals in one pixel without using any color filter.

The photoelectric converters 10 and 80 each have a configuration similar to that of the imaging element 1A according to the embodiment described above. Specifically, in the photoelectric converter 10, the lower electrode 11, the semiconductor layer 13 (the first layer 13A and the second layer 13B), the photoelectric conversion layer 14, and the upper electrode 15 are stacked in this order, as with the imaging element 1A. The lower electrode 11 includes a plurality of electrodes (e.g., the readout electrode 11A and the accumulation electrode 11B). The insulating layer 12 is provided between the lower electrode 11 and the semiconductor layer 13. In the lower electrode 11, the readout electrode 11A is electrically coupled to the semiconductor layer 13 (the first layer 13A) through the opening 12H provided in the insulating layer 12. In the photoelectric converter 80, as with the photoelectric converter 10, a lower electrode 81, a semiconductor layer 83 (a first layer 83A and a second layer 83B), a photoelectric conversion layer 84, and an upper electrode 85 are stacked in this order. The lower electrode 81 includes a plurality of electrodes (e.g., a readout electrode 81A and an accumulation electrode 81B). An insulating layer 82 is provided between the lower electrode 81 and the semiconductor layer 83 (the first layer 83A and the second layer 83B). In the lower electrode 81, the readout electrode 81A is electrically coupled to the semiconductor layer 83 (the first layer 83A) through an opening 82H provided in the insulating layer 82.

A through electrode 91 is coupled to the readout electrode 81A. The through electrode 91 penetrates through an interlayer insulating layer 89 and the photoelectric converter 10, and is electrically coupled to the readout electrode 11A of the photoelectric converter 10. Furthermore, the readout electrode 81A is electrically coupled to the floating diffusion FD provided in the semiconductor substate 30 via through electrodes 34 and 91, and is allowed to temporarily accumulate electric charges generated in the photoelectric conversion layer 84. Furthermore, the readout electrode 81A is electrically coupled to the amplifier transistor AMP and the like provided in the semiconductor substrate 30 through the through electrodes 34 and 91.

### 2-4. Modification Example 4

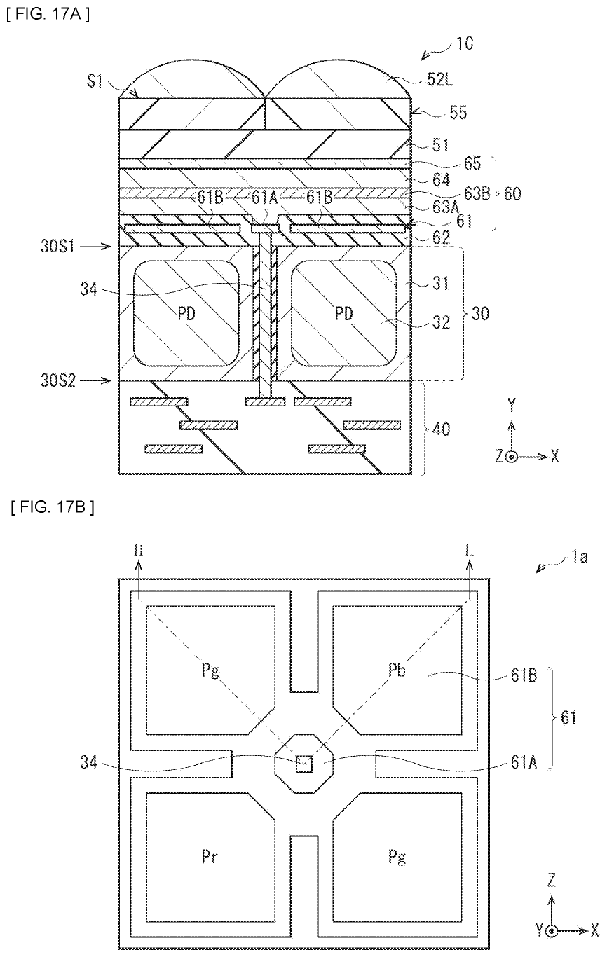

FIG. 17A schematically illustrates a cross-sectional configuration of an imaging element 1C according to the modification example 4 of the present disclosure. FIG. 17B schematically illustrates an example of a planar configuration of the imaging element 1C illustrated in FIG. 17A. FIG. 17A illustrates a cross section taken along a line II-II illustrated in FIG. 17B. The imaging element 1C is, for example, a stacked imaging element in which the photoelectric conversion region 32 and a photoelectric converter 60 are stacked. In the pixel section 100A of an imaging device (e.g., the imaging device 100) including this imaging element 1C, the pixel units 1a are repeatedly disposed as repeating units in an array having the row direction and the column direction. Each of the pixel units 1a includes four pixels that are disposed, for example, in two rows and two columns as illustrated in FIG. 17B.

The imaging element 1C according to the present modification example is provided with color filters 55 above the photoelectric converter 60 (light incidence side S1) for the respective unit pixels P. The color filters 55 allow the red light (R), the green light (G), and the blue light (B) to selectively pass therethrough. Specifically, in the pixel unit 1a including four pixels disposed in two rows and two columns, two color filters each of which allows the green light (G) to selectively pass therethrough are disposed on a diagonal line and one color filter that allows the red light (R) to selectively pass therethrough and one color filter that allows the blue light (B) to selectively pass therethrough are disposed on a diagonal line orthogonal to the diagonal line. In each of the unit pixels (Pr, Pg, and Pb) each provided with a corresponding one of the color filters, corresponding color light is detected, for example, in the photoelectric converter 60. In other words, the pixels (Pr, Pg, and Pb) that respectively detect the red light (R), the green light (G), and the blue light (B) are arranged in a Bayer pattern in the pixel section 100A.

The photoelectric converter 60 absorbs, for example, light corresponding to some or all of wavelengths in the visible light region of 400 nm or more and less than 750 nm and generates excitons (electron-hole pairs). The photoelectric converter 60 includes a lower electrode 61, an insulating layer 62, a semiconductor layer 63 (a first layer 63A and a second layer 63B), a photoelectric conversion layer 64, and an upper electrode 65 that are stacked in this order. The lower electrode 61, the insulating layer 62, the semiconductor layer 63 (the first layer 63A and the second layer 63B), the photoelectric conversion layer 64, and the upper electrode 65 respectively have configurations similar to the lower electrode 11, the insulating layer 12, the semiconductor layer 13 (the first layer 13A and the second layer 13B), the photoelectric conversion layer 14, and the upper electrode 15 of the imaging element 1A according to the embodiment described above. The lower electrode 61 includes, for example, a readout electrode 61A and an accumulation electrode 61B that are independent of each other, and the readout electrode 61A is shared by, for example, four pixels.

The photoelectric conversion region 32 detects, for example, an infrared light region of 750 nm or more and 1300 nm or less.

In the imaging element 1C, each light (the red light (R), the green light (G), and the blue light (B)) in the visible light region of light having passing through the color filter 55 is absorbed by the photoelectric converter 60 of a corresponding one of the unit pixels (Pr, Pg, and Pb) provided with the color filters, and light other than the light, for example, light (infrared light (IR)) in the infrared light region (e.g., 750 nm or more and 1000 nm or less) passes through the photoelectric converter 60. The infrared light (IR) having passed through the photoelectric converter 60 is detected by the photoelectric conversion region 32 of a corresponding one of the unit pixels Pr, Pg, and Pb. Each of the unit pixels Pr, Pg, and Pb generates signal electric charges corresponding to the infrared light (IR). In other words, the imaging device 100 including the imaging element 1C is able to concurrently generate both a visible light image and an infrared light image.

In addition, in the imaging device 100 including the imaging element 1C, it is possible to obtain the visible light image and the infrared light image at the same position in an XZ in-plane direction. Thus, it is possible to achieve high integration in the XZ in-plane direction.

### 2-5. Modification Example 5

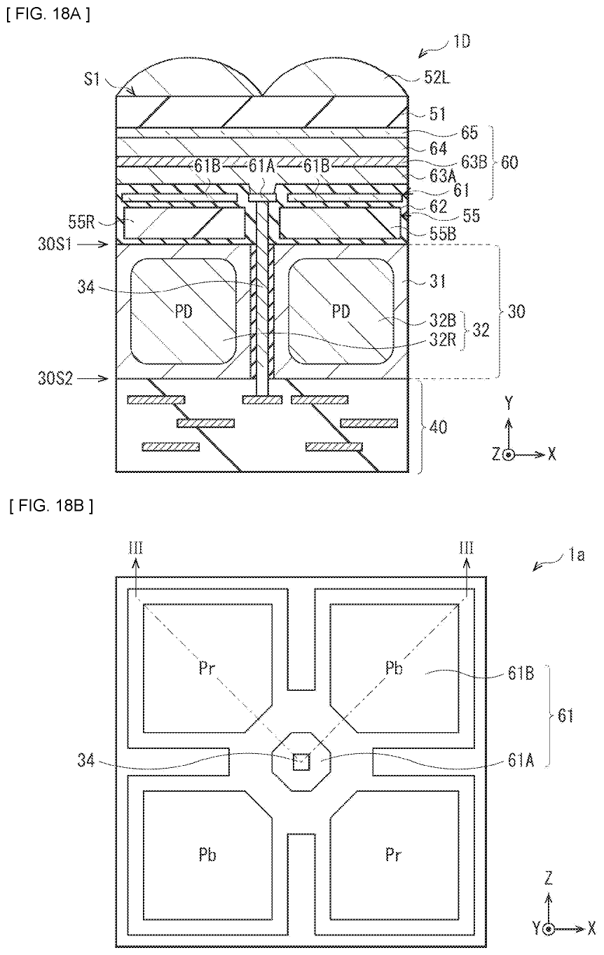

FIG. 18A schematically illustrates a cross-sectional configuration of an imaging element 1D according to the modification example 5 of the present disclosure. FIG. 18B schematically illustrates an example of a planar configuration of the imaging element 1D illustrated in FIG. 18A. FIG. 18A illustrates a cross section taken along a line III-III illustrated in FIG. 18B. In the modification example 4 described above, an example has been described in which the color filter 55 is provided above the photoelectric converter 60 (light incidence side S1); however, the color filter 55 may be provided, for example, between the photoelectric conversion region 32 and the photoelectric converter 60, as illustrated in FIG. 18A.

In the imaging element 1D, the color filter 55 has a configuration in which color filters (color filters 55R) that allow at least the red light (R) to selectively pass therethrough and color filters (color filters 55B) that allow at least the blue light (B) to selectively pass therethrough are disposed diagonally to each other in the pixel unit 1a. The photoelectric converter 60 (the photoelectric conversion layer 64) is configured to selectively absorb, for example, light having wavelengths corresponding to the green light (G). The photoelectric conversion region 32R selectively absorbs light having wavelengths corresponding to the red light (R), and the photoelectric conversion region 32B selectively absorbs light having wavelengths corresponding to the blue light (B). This allows each of the photoelectric conversion regions 32 (the photoelectric conversion regions 32R and 32B) disposed below the photoelectric converter 60 and the color filters 55R and 55B to acquire a signal corresponding to the red light (R), the green light (G), or the blue light (B). The imaging element 1D according to the present modification example allows respective photoelectric converters of R, G, and B to each have a larger area than that in a photoelectric conversion element having a typical Bayer arrangement. This makes it possible to increase an S/N ratio.

### 3. Application Examples

### Application Example 1

FIG. 19 illustrates an example of an entire configuration of an imaging device (the imaging device 100) including the imaging element (e.g., the imaging element 1A) illustrated in FIG. 1 and the like.

The imaging device 100 is, for example, a CMOS image sensor. The imaging device 100 takes in incident light (image light) from a subject through an optical lens system (not illustrated). The imaging device 100 converts the amount of incident light of which an image is formed on an imaging plane into electric signals on a pixel-by-pixel basis and outputs the electric signals as pixel signals. The imaging device 100 includes the pixel section 100A serving as an imaging area on the semiconductor substrate 30. The imaging device 100 includes, for example, a vertical drive circuit 111, a column signal processing circuit 112, a horizontal drive circuit 113, an output circuit 114, a control circuit 115, and an input/output terminal 116 in a peripheral region of this pixel section 100A.

The pixel section 100A includes, for example, a plurality of unit pixels P that is two-dimensionally disposed in rows and columns. The unit pixels P are wired with pixel drive lines Lread (specifically, row selection lines and reset control lines) for respective pixel rows, and are wired vertical signal lines Lsig for respective pixel columns. The pixel drive lines Lread are for transmitting drive signals for signal reading from the pixels. The pixel drive lines Lread each have one end coupled to a corresponding one of output ends, corresponding to the respective rows, of the vertical drive circuit 111.

The vertical drive circuit 111 includes a shift register, an address decoder, and the like, and is a pixel driver that drives the respective unit pixels P of the pixel section 100A, for example, on a row-by-row basis. The signals outputted from the respective unit pixels P in the pixel rows selectively scanned by the vertical drive circuit 111 are supplied to the column signal processing circuits 112 through the respective vertical signal lines Lsig. Each of the column signal processing circuits 112 includes an amplifier, a horizontal selection switch, and the like that are provided for each of the vertical signal lines Lsig.

The horizontal drive circuit 113 includes a shift register, an address decoder, and the like, and drives the respective horizontal selection switches of the column signal processing circuits 112 in order while scanning the horizontal selection switches. This selective scanning by the horizontal drive circuit 113 causes the signals of the respective pixels transmitted through the respective vertical signal lines Lsig to be outputted in sequence to a horizontal signal line 121 and transmitted to outside of the semiconductor substrate 30 through the horizontal signal line 121.

The output circuit 114 performs signal processing on the signals sequentially supplied from the respective column signal processing circuits 112 through the horizontal signal line 121 and outputs the signals. The output circuit 114 performs, for example, only buffering in some cases and performs black level adjustment, column variation correction, various kinds of digital signal processing, and the like in other cases.

The circuit portions including the vertical drive circuit 111, the column signal processing circuits 112, the horizontal drive circuit 113, the horizontal signal line 121, and the output circuit 114 may be formed directly on the semiconductor substrate 30 or may be provided in an external control IC. Alternatively, those circuit portions may be formed in any other substrate coupled by a cable or the like.

The control circuit 115 receives a clock given from the outside of the semiconductor substrate 30, data for an instruction about an operation mode, and the like, and also outputs data such as internal information of the imaging device 100. The control circuit 115 further includes a timing generator that generates various timing signals, and performs drive control of peripheral circuits such as the vertical drive circuit 111, the column signal processing circuit 112, and the horizontal drive circuit 113 on the basis of the various timing signals generated by the timing generator.

The input/output terminal 116 exchanges signals with the outside.

### Application Example 2

The imaging device 100 described above is applicable to various kinds of electronic apparatuses. Examples of the electronic apparatuses include camera systems such as digital still cameras and digital video cameras, mobile phones having imaging functions, and other apparatus having imaging functions.

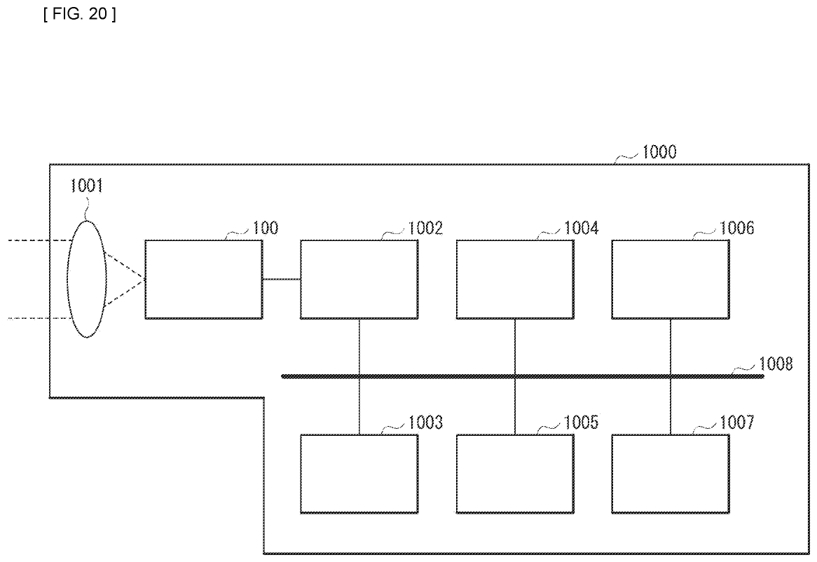

FIG. 20 is a block diagram illustrating a configuration of an electronic apparatus 1000.

As illustrated in FIG. 20, the electronic apparatus 1000 includes an optical system 1001, the imaging device 100, and a DSP (Digital Signal Processor) 1002. The DSP 1002, a memory 1003, a display device 1004, a recording device 1005, an operation system 1006, and a power supply system 1007 are coupled to each other through a bus 1008. It is possible to capture a still image and an moving image.

The optical system 1001 includes one or a plurality of lenses. The optical system 1001 captures incident light (image light) from a subject to form an image on an imaging plane of the imaging device 100.

The imaging device 100 described above is applied as the imaging device 100. The imaging device 100 converts the light amount of the incident light of which the image is formed on the imaging plane by the optical system 1001 into an electric signal on a pixel-by-pixel basis, and supplies the electric signal as a pixel signal to the DSP 1002.

The DSP 1002 performs various kinds of signal processing on a signal from the imaging device 100 to obtain an image, and temporarily stores data of the image in the memory 1003. The data of the image stored in the memory 1003 is stored in the recording device 1005, or is supplied to the display device 1004 to display the image. In addition, the operation system 1006 receives various kinds of operations by a user to supply operation signals to respective blocks of the electronic apparatus 1000. The power supply system 1007 supplies electric power necessary for driving the respective blocks of the electronic apparatus 1000.

### Application Example 3

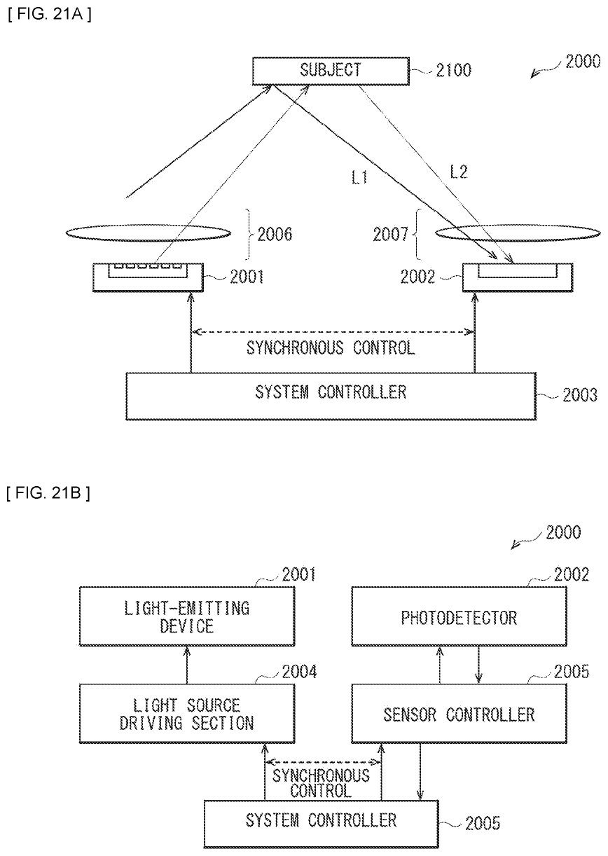

FIG. 21A schematically illustrates an example of an entire configuration of a photodetection system 2000 including the imaging device 100. FIG. 21B illustrates an example of a circuit configuration of the photodetection system 2000. The photodetection system 2000 includes a light-emitting device 2001 as a light source section that emits infrared light L2, and a photodetector 2002 as a light-receiving section including a photoelectric conversion element. As the photodetector 2002, it is possible to use the imaging device 100 described above. The photodetection system 2000 may further include a system controller 2003, a light source driving section 2004, a sensor controller 2005, a light source-side optical system 2006, and a camera-side optical system 2007.

The photodetector 2002 is able to detect light L1 and light L2. The light L1 is ambient light from outside reflected by a subject (a measurement object) 2100 (FIG. 21A). The light L2 is light emitted from the light-emitting device 2001 and then reflected by the subject 2100. The light L1 is, for example, visible light, and the light L2 is, for example, infrared light. The light L1 is detectable by a photoelectric converter in the photodetector 2002, and the light L2 is detectable by a photoelectric conversion region in the photodetector 2002. It is possible to obtain image information of the subject 2100 from the light L1 and obtain distance information between the subject 2100 and the photodetection system 2000 from the light L2. It is possible to mount the photodetection system 2000 on, for example, an electronic apparatus such as a smartphone and a mobile body such as a car. It is possible to configure the light-emitting device 2001 with, for example, a semiconductor laser, a surface-emitting semiconductor laser, or a vertical cavity surface emitting laser (VCSEL). As a method of detecting the light L2 emitted from the light-emitting device 2001 by the photodetector 2002, for example, it is possible to adopt an iTOF method; however, the method is not limited thereto. In the iTOF method, the photoelectric converter is able to measure a distance to the subject 2100 by time of flight (Time-of-Flight; TOF), for example. As a method of detecting the light L2 emitted from the light-emitting device 2001 by the photodetector 2002, it is possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to obtain two or more images of the subject 2100 viewed from two or more different viewpoints, thereby making it possible to measure the distance between the photodetection system 2000 and the subject. It is to be noted that it is possible to synchronously control the light-emitting device 2001 and the photodetector 2002 by the system controller 2003.

### Practical Application Examples

### (Practical Application Example to Endoscopic Surgery System)

The technology according to the present disclosure (present technology) is applicable to various products. For example, the technology according to the present disclosure may be applied to an endoscopic surgery system.

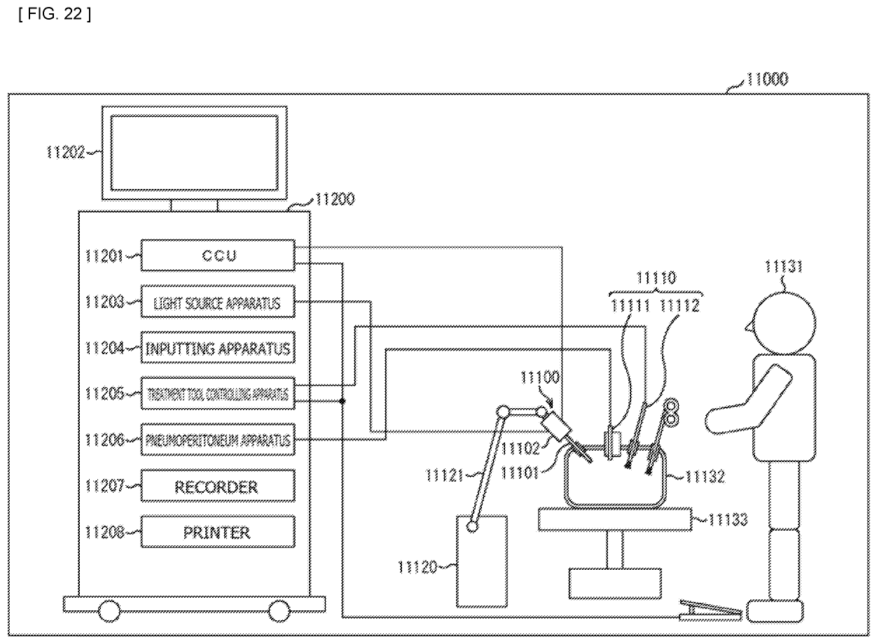

FIG. 22 is a view depicting an example of a schematic configuration of an endoscopic surgery system to which the technology according to an embodiment of the present disclosure (present technology) can be applied.

In FIG. 22, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

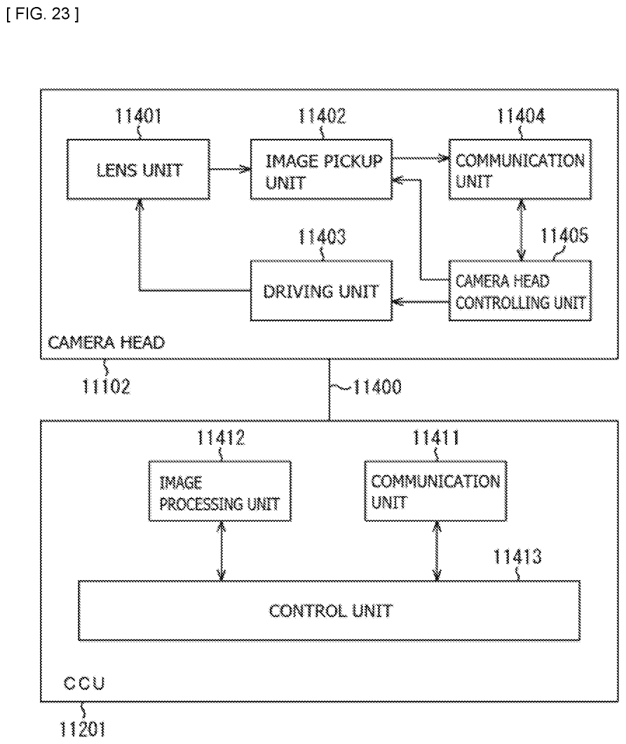

FIG. 23 is a block diagram depicting an example of a functional configuration of the camera head 11102 and the CCU 11201 depicted in FIG. 22.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure may be applied has been described above. The technology according to the present disclosure may be applied to, for example, the image pickup unit 11402 among the configurations described above. Applying the technology according to the present disclosure to the image pickup unit 11402 makes it possible to improve detection accuracy.

It is to be noted that the endoscopic surgery system has been described here as an example, but the technology according to the present disclosure may be additionally applied to, for example, a microscopic surgery system and the like.

### (Practical Application Example to Mobile Body)

The technology according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, a robot, a construction machine, and an agricultural machine (tractor).

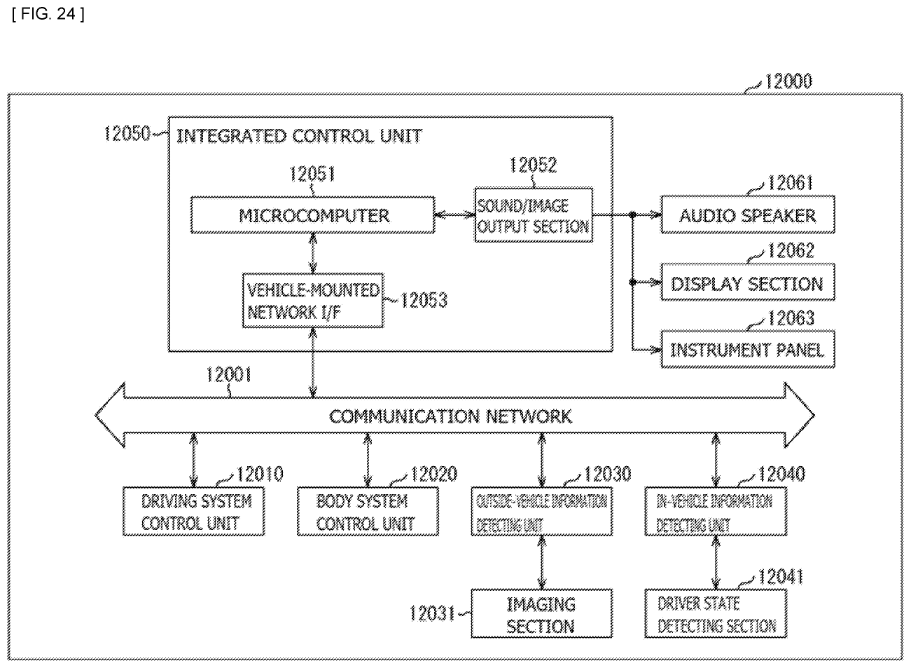

FIG. 24 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

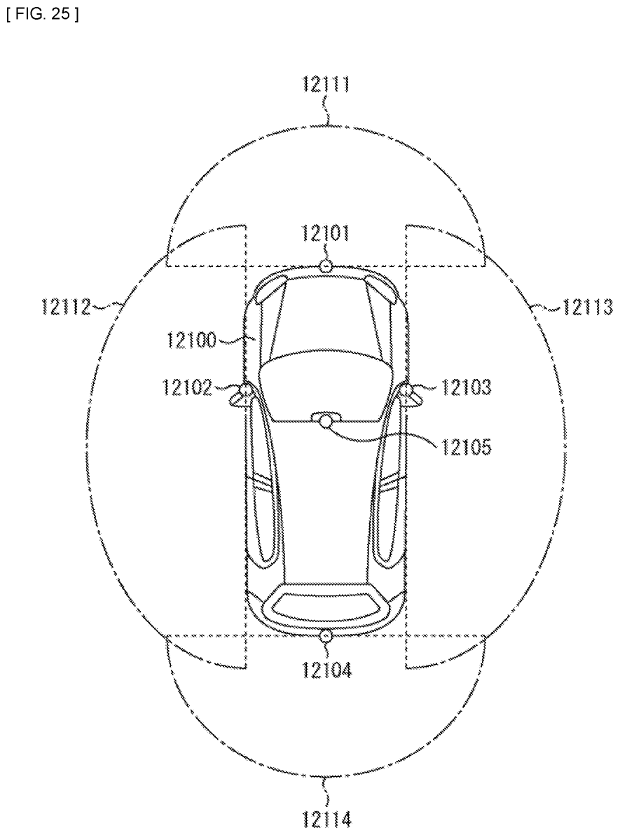

FIG. 25 is a diagram depicting an example of the installation position of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the vehicle control system to which the technology according to the present disclosure may be applied has been described above. The technology according to the present disclosure is appliable to the imaging section 12031 among the configurations described above. Specifically, the imaging element (e.g., the imaging element 1A) according to any of the embodiment described above and the modification examples thereof is applicable to the imaging section 12031. Applying the technology according to the present disclosure to the imaging section 12031 makes it possible to obtain a high-definition shot image with less noise. This makes it possible to perform highly accurate control with use of the shot image in the mobile body control system.

### 5. Examples

Next, description is given of examples of the present disclosure.

### Experimental Example 1

First, a thermally oxidized film having a thickness of 150 nm was formed on a silicon substrate serving as a gate electrode. Thereafter, an TIO film having a thickness of 5 nm was formed as a first layer on the thermally oxidized film. Thereafter, an In₂O₃—SiO (30%) film having a thickness of 30 nm was formed as a second layer on the first layer. Thereafter, a source electrode and a drain electrode were formed. A resultant was an element for evaluation.

### Experimental Example 2

An element for evaluation was fabricated with use of a method similar to that of the experimental example 1, except that the second layer formed in the experimental example 1 was changed to an In₂O₃—SiO (10%) film.

### Experimental Example 3

An element for evaluation was fabricated with use of a method similar to that of the experimental example 1, except that the second layer formed in the experimental example 1 was changed to an In₂O₃—AlO (30%) film.

### Experimental Example 4

An element for evaluation was fabricated with use of a method similar to that of the experimental example 1, except that the second layer formed in the experimental example 1 was changed to an In₂O₃—ZrO (30%) film.

### Experimental Example 5

An element for evaluation was fabricated with use of a method similar to that of the experimental example 1, except that the second layer formed in the experimental example 1 was changed to an In₂O₃—HfO (30%) film.

### Experimental Example 6

An element for evaluation was fabricated with use of a method similar to that of the experimental example 1, except that the first layer formed in the experimental example 1 was changed to an In₂O₃ film.

### Experimental Example 7

An element for evaluation was fabricated with use of a method similar to that of the experimental example 2, except that the first layer formed in the experimental example 2 was changed to an In₂O₃ film.

### Experimental Example 8

An element for evaluation was fabricated with use of a method similar to that of the experimental example 3, except that the first layer formed in the experimental example 3 was changed to an In₂O₃ film.

### Experimental Example 9

An element for evaluation was fabricated with use of a method similar to that of the experimental example 5, except that the first layer formed in the experimental example 5 was changed to an In₂O₃ film.

### Experimental Example 10

An element for evaluation was fabricated with use of a method similar to that of the experimental example 4, except that the first layer formed in the experimental example 4 was changed to an In₂O₃ film.

### Experimental Example 11

An element for evaluation was fabricated with use of a method similar to that of the experimental example 1, except that the second layer formed in the experimental example 1 was changed to a Zn—Sn—O film.

### Experimental Example 12

An element for evaluation was fabricated with use of a method similar to that of the experimental example 1, except that the first layer and the second layer formed in the experimental example 1 were respectively changed to a c-In—Ga—Zn—O film and an In—Ga—Zn—Si—O film.

### Experimental Example 13

An element for evaluation was fabricated with use of a method similar to that of the experimental example 1, except that the first layer formed in the experimental example 1 was omitted.

### Experimental Example 14

An element for evaluation was fabricated with use of a method similar to that of the experimental example 1, except that the first layer formed in the experimental example 1 was changed to a ZnO film.

TABLE 1

| | | Second Layer | | | | | | | | | | |
|---|---|---|---|---|---|---|---|---|---|---|---|---|
| | | | Narrow Band Gap | | | | | | | | | |
| | | | Material | | Wide Band Gap Material | | | | | | | |
| | | | Bond Dissociation | | | | Bond Dissociation | | | | | |
| | | | Energy | | Band Gap | | Energy | | Content | ΔVth | Low-temperature | Heat |
| | First Layer | Material | [eV] | | [eV] | | [eV] | | [%] | [V] | Film Formation | Resistance |
| Experimental | In—Sn—O | In₂O₃—SiO | 3.6 | In₂O₃ | 9.0 | SiO | 8.3 | SiO | 30 | A | A | A |
| Example 1 | | | | | | | | | | | | |
| Experimental | In—Sn—O | In₂O₃—SiO | 3.6 | In₂O₃ | 9.0 | SiO | 8.3 | SiO | 10 | A | A | A |
| Example 2 | | | | | | | | | | | | |
| Experimental | In—Sn—O | In₂O₃—AlO | 3.6 | In₂O₃ | 8.8 | AlO | 5.2 | AlO | 30 | A | A | A |
| Example 3 | | | | | | | | | | | | |
| Experimental | In—Sn—O | In₂O₃—ZrO | 3.6 | In₂O₃ | 5.8 | ZrO | 7.9 | ZrO | 30 | A | A | A |
| Example 4 | | | | | | | | | | | | |
| Experimental | In—Sn—O | In₂O₃—HfO | 3.6 | In₂O₃ | 5.7 | HfO | 8.3 | HfO | 30 | A | A | A |
| Example 5 | | | | | | | | | | | | |
| Experimental | In₂O₃ | In₂O₃—SiO | 3.6 | In₂O₃ | 9.0 | SiO | 8.3 | SiO | 30 | A | A | A |
| Example 6 | | | | | | | | | | | | |
| Experimental | In₂O₃ | In₂O₃—SiO | 3.6 | In₂O₃ | 9.0 | SiO | 8.3 | SiO | 10 | A | A | A |
| Example 7 | | | | | | | | | | | | |

TABLE 2

| | | Second Layer | | | | | | | | | | |
|---|---|---|---|---|---|---|---|---|---|---|---|---|
| | | | Narrow Band | | | | | | | | | |
| | | | Gap Material | | Wide Band Gap Material | | | | | | Low- | |
| | | | Bond | | | | Bond | | | | temperature | |
| | | | Dissociation | | | | Dissociation | | | | | |
| | | | Energy | | Band Gap | | Energy | | Content | ΔVth | Film | Heat |
| | First Layer | Material | [eV] | | [eV] | | [eV] | | [%] | [V] | Formation | Resistance |
| Experimental | In₂O₃ | In₂O₃—AlO | 3.6 | In₂O₃ | 8.8 | AlO | 5.2 | AlO | 30 | A | A | A |
| Example 8 | | | | | | | | | | | | |
| Experimental | In₂O₃ | In₂O₃—HfO | 3.6 | In₂O₃ | 5.7 | HfO | 8.3 | HfO | 30 | A | A | A |
| Example 9 | | | | | | | | | | | | |
| Experimental | In₂O₃ | In₂O₃—ZrO | 3.6 | In₂O₃ | 5.8 | ZrO | 7.9 | ZrO | 30 | A | A | A |
| Example 10 | | | | | | | | | | | | |
| Experimental | In—O | Zn—Sn—O | 2.6 | ZnO | 3.8 | SnO | 5.5 | SnO | — | B | B | B |
| Example 11 | | | | | | | | | | | | |
| Experimental | c-In—Ga—Zn—O | In—Ga—Zn—Si—O | 2.6 | ZnO | 9.0 | SiO | 8.3 | SiO | — | B | B | B |
| Example 12 | | | | | | | | | | | | |
| Experimental | — | In₂O₃—SiO | 3.6 | In₂O₃ | 9.0 | SiO | 8.3 | SiO | 30 | B | A | A |
| Example 13 | | | | | | | | | | | | |
| Experimental | ZnO | In₂O₃—SiO | 2.6 | ZnO | 9.0 | SiO | 8.3 | SiO | 30 | B | B | B |
| Example 14 | | | | | | | | | | | | |

Table 1 and Table 2 summarize configurations of the first layer and the second layer used in the experimental examples 1 to 14, bond dissociation energy of the first oxide materials (narrow band gap materials) used for the second layer, and the band gaps, bond dissociation energy, and contents of the second oxide materials (wide band gap materials), and mobility (threshold voltages), film formation temperature, and heat resistance.

A basic S value and basic mobility were calculated from an ID-VGS curve obtained from TFT evaluation. A hysteresis characteristic ΔVth caused by a trap affecting transfer characteristics and afterimage characteristics was evaluated. A smaller hysteresis amount leads to superior transfer characteristics and superior afterimage characteristics. In Table 1 and Table 2, A indicates a case where ΔVth was less than 0.1, and B indicates a case where Δth was 0.1 or more. As for low-temperature film formation, A indicates a case where ΔVth was less than 0.1 at a film formation temperature of less than 200° C., and B indicates a case where ΔVth was 0.1 or more at a film formation temperature of less than 200° C. As for heat resistance, A indicates a case where the characteristics were not changed before and after heat treatment at 200° C., and B indicates a case where the characteristics were changed before and after the heat treatment at 200° C.

In the experimental examples 1 to 10 formed using the first oxide material having a carrier concentration of 1E19 cm⁻³ or more and 1E21 cm⁻³ or less and bond dissociation energy of 3.58 eV or more and 5.50 eV or less as the material included in the first layer and using the first oxide material and the second oxide material having a band gap of 4.5 eV or more and bond dissociation energy of 4.0 eV or more and 8.8 eV or less as the materials included in the second layer, sufficient mobility was obtained in low-temperature film formation at less than 200° C. In addition, it was found that the experimental examples 1 to 10 had sufficient heat resistance. In contrast, in the experimental examples 11 to 14 in which the first layer was omitted or a material not suitable for the first oxide material or the second oxide material described above was used, it was confirmed that mobility and heat resistance were decreased, as compared with the experimental examples 1 to 10.

Although the present technology has been described with reference to the embodiment, the modification examples 1 to 5, the application examples, the practical application examples, and the examples, the contents of the present disclosure are not limited to the embodiment and the like described above, and may be modified in a variety of ways. For example, in the embodiment and the like described above, an example has been described in which electrons are read out from side of the lower electrode 11 as signal electric charges, but this is not limitative. Holes may be read out from side of the lower electrode 11 as signal electric charges.

In addition, in the embodiment described above, the imaging element 1A has a configuration in which the photoelectric converter 10 using an organic material that detects the green light (G), and the photoelectric conversion region 32B and the photoelectric conversion region 32R that respectively detect the blue light (B) and the red light (R) are stacked. However, the contents of the present disclosure are not limited to such a structure. That is, a photoelectric converter using an organic material may detect the red light (R) or the blue light (B), and a photoelectric conversion region including an inorganic material may detect the green light (G).

Furthermore, the number of the photoelectric converters using the organic material, the number of the photoelectric conversion regions including the inorganic material and the ratio thereof are not limited. Furthermore, without limitation to a structure in which the photoelectric converter using the organic material and the photoelectric conversion region including the inorganic material are stacked in the longitudinal direction, the photoelectric converter and the photoelectric conversion region may be disposed in parallel along a substrate surface.

Furthermore, in the embodiment and the like described above, the configuration of the back-illuminated imaging element is exemplified, but the contents of the present disclosure are applicable to a front-illuminated imaging element.

Furthermore, the photoelectric converter 10, the imaging element 1A, and the like, and the imaging device 100 may not necessarily include all the components described in the embodiment described above, or contrarily may include any other component. For example, in the imaging device 100, a shutter for controlling entry of light into the imaging element 1A may be disposed, or an optical cut filter may be provided according to the purpose of the imaging device 100. In addition, arrangement of pixels (Pr, Pg, and Pb) that detect the red light (R), the green light (G), and the blue light B) may be an interline arrangement, a G stripe RB checkered arrangement, a G stripe RB full checkered arrangement, a checkered complementary color arrangement, a stripe arrangement, a diagonal stripe arrangement, a primary color difference arrangement, a field color difference sequential arrangement, a frame color difference sequential arrangement, a MOS arrangement, an improved MOS arrangement, a frame interleave arrangement, or a field interleave arrangement, in place of the Bayer arrangement.

In addition, the photoelectric converter 10 of the present disclosure may be applied to a solar battery. In a case where the photoelectric converter 10 is applied to a solar battery, it is preferable that the photoelectric conversion layer be designed to broadly absorb wavelengths of 400 nm to 800 nm, for example.

It is to be noted that the effects described herein are merely illustrative and non-limiting, and other effects may be provided.

It is to be noted that the present disclosure may have the following configurations. According to the present technology having the following configurations, a semiconductor layer is provided between a first electrode and a second electrode that are disposed in parallel, and a photoelectric conversion layer. The semiconductor layer includes a first layer and a second layer stacked in this order from side of the first electrode and the second electrode. The first layer is formed using a first oxide material having a carrier concentration of 1E19 cm⁻³ or more and 1E21 cm⁻³ or less and bond dissociation energy of 3.58 eV or more and 5.50 eV or less. In a first imaging element, the second layer is formed using the first oxide material and a second oxide material having a band gap of 4.5 eV or more and bond dissociation energy of 4.0 eV or more and 8.8 eV or less. Electric charges generated in the photoelectric conversion layer to stagnate at an interface between the photoelectric conversion layer and the semiconductor layer are reduced, and electric charges move well in the semiconductor layer. This makes it possible to improve transfer characteristics and afterimage characteristics.

(1)

An imaging element including:
a first electrode and a second electrode that are disposed in parallel;
a third electrode that is disposed to be opposed to the first electrode and the second electrode;
a photoelectric conversion layer that is provided between the first electrode and second electrode, and the third electrode, and includes an organic material; and
a semiconductor layer including a first layer and a second layer that are stacked in order from side of the first electrode and the second electrode between the first electrode and second electrode, and the photoelectric conversion layer, in which
the first layer includes a first oxide material having a carrier concentration of 1E19 cm⁻³ or more and 1E21 cm⁻³ or less and bond dissociation energy of 3.58 eV or more and 5.50 eV or less, and
the second layer includes the first oxide material and a second oxide material having a band gap of 4.5 eV or more and bond dissociation energy of 4.0 eV or more and 8.8 eV or less.
   (2)

The imaging element according to (1), in which the first oxide material includes indium oxide.

(3)

The imaging element according to (2), in which the first oxide material further includes tin oxide.

(4)

The imaging element according to any one of (1) to (3), in which the second oxide material includes silicon oxide, aluminum oxide, zirconium oxide, and hafnium oxide.

(5)

The imaging element according to any one of (1) to (4), in which the second layer includes the second oxide material at a ratio of 5 at % or more and 70 at % or less.

(6)

The imaging element according to any one of (1) to (5), in which a ratio (t2/t1) of a thickness (t2) of the second layer to a thickness (t1) of the first layer is 4 or more and 8 or less.

(7)

The imaging element according to any one of (1) to (6), further including an insulating layer that is provided between the first electrode and second electrode, and the semiconductor layer, and has an opening above the second electrode, in which
the second electrode and the semiconductor layer are electrically coupled through the opening.
   (8)

The imaging element according to any one of (1) to (7), further including a protective layer between the photoelectric conversion layer and the semiconductor layer, the protective layer including an inorganic material.

(9)

The imaging element according to any one of (1) to (8), in which the first electrode and the second electrode are disposed on the photoelectric conversion layer on side opposite to a light incidence surface.

(10)

The imaging element according to any one of (1) to (9), in which respective voltages are individually applied to the first electrode and the second electrode.

(11)

The imaging element according to any one of (1) to (10), further including a fourth electrode provided between the first electrode and the second electrode.

(12)

The imaging element according to (11), in which the fourth electrode is formed below the first electrode and the second electrode, and a portion of the fourth electrode vertically overlaps with the first electrode and the second electrode.

(13)

The imaging element according to any one of (1) to (12), in which one or a plurality of photoelectric converters and one or a plurality of photoelectric conversion regions are stacked, the photoelectric converters each including the first electrode, the second electrode, the third electrode, the photoelectric conversion layer, and the semiconductor layer, and the photoelectric conversion regions each performing photoelectric conversion in a wavelength range different from a wavelength range of each of the photoelectric converters.

(14)

The imaging element according to (13), in which
the photoelectric conversion region is formed to be buried in a semiconductor substrate, and
the photoelectric converter is formed on side of a first surface of the semiconductor substrate.
   (15)

The imaging element according to (14), in which the semiconductor substrate has the first surface and a second surface that are opposed to each other and has a multilayer wiring layer formed on side of the second surface.

(16)

An imaging device including:
a plurality of pixels that is each provided with one or a plurality of imaging elements, in which the imaging elements each include
a first electrode and a second electrode that are disposed in parallel,
a third electrode that is disposed to be opposed to the first electrode and the second electrode,
a photoelectric conversion layer that is provided between the first electrode and second electrode, and the third electrode, and includes an organic material, and
a semiconductor layer including a first layer and a second layer that are stacked in order from side of the first electrode and the second electrode between the first electrode and second electrode, and the photoelectric conversion layer,
the first layer includes a first oxide material having a carrier concentration of 1E19 cm⁻³ or more and 1E21 cm⁻³ or less and bond dissociation energy of 3.58 eV or more and 5.50 eV or less, and
the second layer includes the first oxide material and a second oxide material having a band gap of 4.5 eV or more and bond dissociation energy of 4.0 eV or more and 8.8 eV or less.

This application claims the priority on the basis of Japanese Patent Application No. 2021-147548 filed on Sep. 10, 2021 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. An imaging element comprising:
a first electrode and a second electrode that are disposed in parallel;
a third electrode that is disposed to be opposed to the first electrode and the second electrode;
a photoelectric conversion layer that is provided between the first electrode and second electrode, and the third electrode, and includes an organic material; and
a semiconductor layer including a first layer and a second layer that are stacked in order from side of the first electrode and the second electrode between the first electrode and second electrode, and the photoelectric conversion layer, wherein
the first layer includes a first oxide material having a carrier concentration of 1E19 cm⁻³ or more and 1E21 cm⁻³ or less and bond dissociation energy of 3.58 eV or more and 5.50 eV or less, and
the second layer includes the first oxide material and a second oxide material having a band gap of 4.5 eV or more and bond dissociation energy of 4.0 eV or more and 8.8 eV or less.

2. The imaging element according to claim 1, wherein the first oxide material includes indium oxide.

3. The imaging element according to claim 2, wherein the first oxide material further includes tin oxide.

4. The imaging element according to claim 1, wherein the second oxide material includes silicon oxide, aluminum oxide, zirconium oxide, and hafnium oxide.

5. The imaging element according to claim 1, wherein the second layer includes the second oxide material at a ratio of 5 at % or more and 70 at % or less.

6. The imaging element according to claim 1, wherein a ratio (t2/t1) of a thickness (t2) of the second layer to a thickness (t1) of the first layer is 4 or more and 8 or less.

7. The imaging element according to claim 1, further comprising an insulating layer that is provided between the first electrode and second electrode, and the semiconductor layer, and has an opening above the second electrode, wherein
the second electrode and the semiconductor layer are electrically coupled through the opening.

8. The imaging element according to claim 1, further comprising a protective layer between the photoelectric conversion layer and the semiconductor layer, the protective layer including an inorganic material.

9. The imaging element according to claim 1, wherein the first electrode and the second electrode are disposed on the photoelectric conversion layer on side opposite to a light incidence surface.

10. The imaging element according to claim 1, wherein respective voltages are individually applied to the first electrode and the second electrode.

11. The imaging element according to claim 1, further comprising a fourth electrode provided between the first electrode and the second electrode.

12. The imaging element according to claim 11, wherein the fourth electrode is formed below the first electrode and the second electrode, and a portion of the fourth electrode vertically overlaps with the first electrode and the second electrode.

13. The imaging element according to claim 1, wherein one or a plurality of photoelectric converters and one or a plurality of photoelectric conversion regions are stacked, the photoelectric converters each including the first electrode, the second electrode, the third electrode, the photoelectric conversion layer, and the semiconductor layer, and the photoelectric conversion regions each performing photoelectric conversion in a wavelength range different from a wavelength range of each of the photoelectric converters.

14. The imaging element according to claim 13, wherein
the photoelectric conversion region is formed to be buried in a semiconductor substrate, and
the photoelectric converter is formed on side of a first surface of the semiconductor substrate.

15. The imaging element according to claim 14, wherein the semiconductor substrate has the first surface and a second surface that are opposed to each other and has a multilayer wiring layer formed on side of the second surface.

16. An imaging device comprising:
a plurality of pixels that is each provided with one or a plurality of imaging elements, wherein the imaging elements each include
a first electrode and a second electrode that are disposed in parallel,
a third electrode that is disposed to be opposed to the first electrode and the second electrode,
a photoelectric conversion layer that is provided between the first electrode and second electrode, and the third electrode, and includes an organic material, and
a semiconductor layer including a first layer and a second layer that are stacked in order from side of the first electrode and the second electrode between the first electrode and second electrode, and the photoelectric conversion layer,
the first layer includes a first oxide material having a carrier concentration of 1E19 cm⁻³ or more and 1E21 cm⁻³ or less and bond dissociation energy of 3.58 eV or more and 5.50 eV or less, and
the second layer includes the first oxide material and a second oxide material having a band gap of 4.5 eV or more and bond dissociation energy of 4.0 eV or more and 8.8 eV or less.
